(19) United States
(12) Patent Application Publication
(10) Pub. No.: US 2026/0026204 A1
(43) Pub. Date: Jan. 22, 2026

(54) DISPLAY PANEL AND ELECTRONIC DEVICE INCLUDING THE SAME

(71) Applicant: SAMSUNG DISPLAY CO., LTD., YONGIN-SI (KR)

(72) Inventors: JUCHAN PARK, Yongin-si (KR); YOOMIN KO, Yongin-si (KR); SUNHO KIM, Yongin-si (KR); CHUNG SOCK CHOI, Yongin-si (KR); Hyewon KIM, Yongin-si (KR)

(21) Appl. No.: 19/270,718

(22) Filed: Jul. 16, 2025

(30) Foreign Application Priority Data
Jul. 19, 2024 (KR) 10-2024-0095427

(51) Int. Cl. H10K 59/122

(52) U.S. Cl. CPC H10K 59/122

(57) ABSTRACT

An electronic device including a display panel having display and peripheral regions, the display panel includes: a driving element layer including a pixel driver; light-emitting elements including a first electrode, an intermediate layer, and a second electrode; a pixel definition layer on the driving element layer and having a light-emitting opening exposing a portion of the first electrode; a connection electrode on the pixel definition layer and electrically connecting the pixel driver and the second electrode; and separators on the pixel definition layer and protruding in a thickness direction of the driving element layer, wherein the of separators include: first separators in the display region or the peripheral region; and second separator in the peripheral region, wherein the second separators include: a first region overlapping the connection electrode in a planar view; and a second region that does not overlap the connection electrode in a planar view.

### CROSS-REFERENCE TO RELATED APPLICATION

This U.S. non-provisional patent application claims priority under 35 U.S.C. § 119 to Korean Patent Application No. 10-2024-0095427, filed on Jul. 19, 2024, the disclosure which is incorporated by reference herein in its entirety.

### TECHNICAL FIELD

The present disclosure relates to a display panel and an electronic device, and more particularly, to a display panel and an electronic device with improved display quality.

### DISCUSSION OF RELATED ART

Electronic devices including televisions, monitors, smartphones, and tablets that provide visual content to users, are equipped with display panels for image presentation. Various types of display panels are being developed such as liquid crystal display panels, organic light-emitting display panels, electro wetting display panels, and electrophoretic display panels.

### SUMMARY

The present disclosure provides a display panel designed to minimize afterimage defects and improve lifespan, as well as an electronic device incorporating such a display panel.

An embodiment of the inventive concept provides an electronic device comprising a display panel having a display region and a peripheral region adjacent to the display region, the display panel comprises: a driving element layer comprising a pixel driver; a plurality of light-emitting elements overlapping the display region, wherein each of the light-emitting elements comprises a first electrode, an intermediate layer disposed on the first electrode, and a second electrode disposed on the intermediate layer; a pixel definition layer disposed on the driving element layer and having a light-emitting opening exposing a portion of the first electrode; a connection electrode disposed on the pixel definition layer and electrically connecting the pixel driver and the second electrode to each other; and a plurality of separators disposed on the pixel definition layer and protruding in a thickness direction of the driving element layer, wherein the plurality of separators comprise: a plurality of first separators disposed in the display region or the peripheral region; and a plurality of second separators disposed in the peripheral region, wherein the plurality of second separators comprise: a first region overlapping the connection electrode in a planar view; and a second region that does not overlap the connection electrode in a planar view.

The display panel further comprises: a dummy layer disposed on the plurality of first separators; and an outer dummy layer disposed on the plurality of second separators, wherein the outer dummy layer extends toward the peripheral region and is electrically connected to the first electrode in the peripheral region.

The intermediate layer and the second electrode overlapping the display region are disconnected by the plurality of first separators; and the intermediate layer and the second electrode adjacent to the first region of the plurality of second separators are disconnected by the plurality of second separators.

A first angle formed between a lower surface of the plurality of second separators and a first side surface of the plurality of second separators in the first region is larger than a second angle formed between the lower surface of the plurality of second separators and a second side surface of the plurality of second separators in the second region.

A thickness of the pixel definition layer adjacent to the second region is smaller than a thickness of the pixel definition layer adjacent to the first region.

The driving element layer comprises: a first driving insulating layer covering the pixel driver; and a second driving insulating layer disposed on the first driving insulating layer.

A thickness of the first driving insulating layer adjacent to the second region is smaller than a thickness of the first driving insulating layer adjacent to the first region.

A thickness of the second driving insulating layer adjacent to the second region is smaller than a thickness of the second driving insulating layer adjacent to the first region.

The display panel further comprises a first protrusion pattern disposed on the pixel definition layer and the plurality of second separators, wherein the first protrusion pattern is adjacent to the second region.

The display panel further comprises an outer dummy layer disposed on the plurality of second separators and the first protrusion pattern, wherein the outer dummy layer extends toward the peripheral region and is electrically connected to the first electrode in the peripheral region.

The display panel further comprises a second protrusion pattern disposed between the plurality of second separators and the pixel definition layer.

A width of the second protrusion pattern in one direction is larger than a width of the plurality of second separators in the one direction.

A width of the second protrusion pattern in one direction is smaller than a width of the plurality of second separators in the one direction; and the second protrusion pattern is spaced apart from the connection electrode on the plane.

The peripheral region comprises a first edge region, a second edge region, a third edge region, and a fourth edge region which surround the display region, wherein: the first edge region and the third edge region extend in a first direction; and the second edge region and the fourth edge region extend in a second direction crossing the first direction.

The plurality of second separators are disposed in the first to fourth edge regions.

The plurality of second separators are disposed in at least one of the first to fourth edge regions; and the plurality of first separators are disposed in at least one of the first to fourth edge regions where the plurality of second separators are not disposed.

The plurality of first separators are disposed in at least one of the first to fourth edge regions; and the plurality of first separators and the plurality of second separators are alternately arranged in at least one of the first to fourth edge regions where the plurality of first separators are not solely disposed.

The plurality of first separators are disposed in a first portion of the first to fourth edge regions; the plurality of second separators are disposed in a second portion of the first to fourth edge regions; and the plurality of first separators and the plurality of second separators are alternately arranged in a third portion of the first to fourth edge regions.

An embodiment of the inventive concept provides a display panel including: a driving element layer comprising a pixel driver; a plurality of light-emitting elements each comprising a first electrode disposed on the driving element layer, an intermediate layer disposed on the first electrode, and a second electrode disposed on the intermediate layer; a pixel definition layer disposed on the driving element layer and having a light-emitting opening exposing a portion of the first electrode; a connection electrode disposed on the pixel definition layer and electrically connecting the pixel driver and the second electrode to each other; and a plurality of separators disposed on the pixel definition layer and protruding in a thickness direction of the driving element layer, wherein the plurality of separators comprise: a plurality of first separators having a symmetrical shape; and a plurality of second separators having an asymmetrical shape.

The display panel further comprising: a dummy layer disposed on the plurality of first separators; and an outer dummy layer disposed on the plurality of second separators, wherein the outer dummy layer is electrically connected to the first electrode.

An embodiment of the inventive concept provides a display panel comprising: a driving element layer comprising a pixel driver; a light-emitting element comprising a first electrode disposed on the driving element layer, an intermediate layer disposed on the first electrode, and a second electrode disposed on the intermediate layer; a pixel definition layer disposed on the driving element layer and having a light-emitting opening exposing a portion of the first electrode; a connection electrode disposed on the pixel definition layer and electrically connecting the pixel driver and the second electrode to each other; and a plurality of separators disposed on the pixel definition layer and protruding in a thickness direction of the driving element layer, wherein the plurality of separators comprise: a first separator and a second separator, wherein a first side of the second separator is more deeply recessed than a second side of the second separator such that a gap is formed between the intermediate layer and between the second electrode at the first side of the second separator.

### BRIEF DESCRIPTION OF THE DRAWINGS

The accompanying drawings are provided to enhance understanding of the inventive concept. These drawings are incorporated into and form a part of this specification, illustrating embodiments of the inventive concept and, together with the description, explaining it principles. In the drawings:

FIG. 1 is a block diagram of an electronic device according to an embodiment of the inventive concept;

FIG. 2A, FIG. 2B, and FIG. 2C are equivalent circuit diagrams of pixels according to an embodiment of the inventive concept;

FIG. 3A and FIG. 3B are plan views schematically illustrating a display panel according to an embodiment of the inventive concept;

FIG. 4A, FIG. 4B, FIG. 4C and FIG. 4D are enlarged plan views of a portion of the display panel according to an embodiment of the inventive concept;

FIG. 5 is a cross-sectional view of the display panel according to an embodiment of the inventive concept;

FIG. 6, FIG. 7, FIG. 8, FIG. 9, FIG. 10 and FIG. 11 are enlarged views of a region corresponding to region AA′ of FIG. 5; and

FIG. 12A, FIG. 12B, FIG. 12C and FIG. 12D are schematic plan views illustrating a display region and a peripheral region according to an embodiment of the inventive concept.

### DETAILED DESCRIPTION OF THE EMBODIMENT

In this specification, it will be understood that when an element (or region, layer, portion, etc.) is referred to as being “on”, “connected to” or “coupled to” another element, it can be directly on, connected or coupled to the other element, or intervening elements may be present.

Throughout the description, like reference numerals denote like elements. In addition, in the drawings, the thicknesses, ratios, and dimensions of elements may be exaggerated to effectively illustrate the technical details. As used herein, the term “and/or” includes any and all combinations of the associated configurations.

It will be understood that, although the terms first, second, etc. may be used herein to describe various elements, these elements should not be limited by these terms. These terms are used to distinguish one element from another element. For example, a first element could be termed a second element. Similarly, the second element may also be referred to as the first element. The terms of a singular form include plural forms unless otherwise specified.

In addition, terms, such as “below”, “lower”, “above”, “upper” and the like, are used herein for convenience to the relationship between elements as illustrated in the figures. These terms are relative concepts and are based on the directions indicated in the drawings.

It will be understood that the terms “include” and/or “have”, when used in this specification, specify the presence of stated features, integers, steps, operations, elements, components and/or groups thereof, but do not preclude the presence or addition of one or more other features, integers, steps, operations, elements, components, and/or groups thereof.

Unless otherwise defined, all terms (including technical and scientific terms) used herein have the meaning commonly understood by those of ordinary skill in the art to which this invention belongs. It will be further understood that terms, such as those defined in commonly used dictionaries, should be interpreted in a manner that is consistent with their use in the context of the relevant field and should not be interpreted in an idealized or overly formal sense unless expressly stated otherwise.

Hereinafter, embodiments of the inventive concept will be described with reference to the drawings.

This invention concerns an electronic device, specifically a display panel with a display region and an adjacent peripheral region. It addresses the reduction of touch noise and electric field fluctuations caused by floating dummy layers and separators in the display panel structure. Key features include a pixel driver, light-emitting elements, and a pixel definition layer with light-emitting openings. Separators in the structure are strategically placed and designed to connect dummy layers to reduce floating effects and stabilize current flow, thereby improving touch response and display performance.

Notably, the invention eliminates the need for a lower TCO (Transparent Conductive Oxide) on outer separators by connecting upper separators to an electrical node (ELVDD). This prevents floating electrodes and mitigates the adverse effects of electric field fluctuations and current inconsistencies in the dummy layer and outer dummy layer.

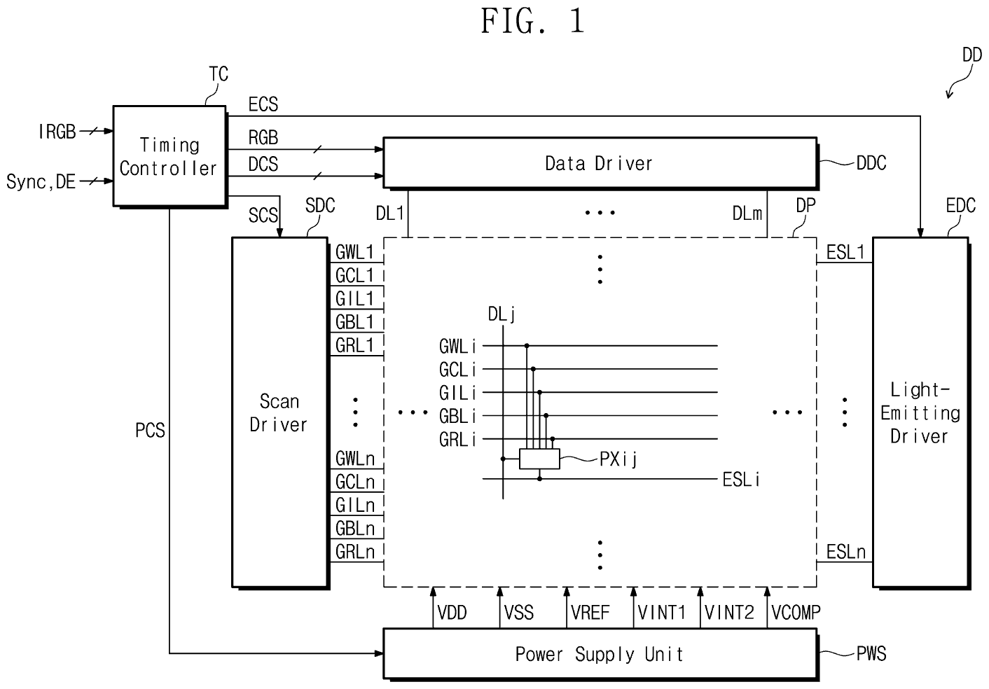

FIG. 1 is a block diagram of an electronic device DD according to an embodiment of the inventive concept.

Referring to FIG. 1, the electronic device DD may include a display panel DP, a panel driving unit SDC, EDC, and DDC, a power supply unit PWS, and a timing controller TC. In this embodiment, the display panel DP is described as a light-emitting display panel. The light-emitting display panel may include an organic light-emitting display panel, an inorganic light-emitting display panel, or a quantum dot light-emitting display panel. In embodiments to be described later, an organic light-emitting display panel will be described in detail as an example. The panel driving unit SDC, EDC, and DDC may include a scan driver SDC, a light-emitting driver EDC, and a data driver DDC.

The display panel DP may include scan lines GWL1 to GWLn, GCL1 to GCLn, GIL1 to GILn, GBL1 to GBLn, and GRL1 to GRLn, light-emitting lines ESLI to ESLn, and data lines DL1 to DLm. The display panel DP may include a plurality of pixels connected to the scan lines GWL1 to GWLn, GCL1 to GCLn, GIL1 to GILn, GBL1 to GBLn, and GRL1 to GRLn, the light-emitting lines ESL1 to ESLn, and the data lines DL1 to DLm (wherein m and n are integers greater than 1).

For example, a pixel PXij (i and j are integers greater than 1) located on an i-th horizontal line (or an i-th pixel row) and a j-th vertical line (or a j-th pixel column) may be connected to an i-th first scan line GWLi (or write scan line), an i-th second scan line GCLi (or compensation scan line), an i-th third scan line GILi (or first initialization scan line), an i-th fourth scan line GBLi (or second initialization scan line), an i-th fifth scan line GRLi (or reset scan line), a j-th data line DLj, and an i-th light-emitting line ESLi.

The pixel PXij may include a plurality of light-emitting elements, a plurality of transistors, and a plurality of capacitors. The pixel PXij may receive, through the power supply unit PWS, a first power voltage VDD, a second power voltage VSS, a third power voltage VREF (or reference voltage), a fourth power voltage VINT1 (or first initialization voltage), a fifth power voltage VINT2 (or second initialization voltage), and a sixth power voltage VCOMP (or compensation voltage).

The values of the first power voltage VDD and the second power voltage VSS are set to allow current to flow into a light-emitting element, enabling it to emit light. For example, the first power voltage VDD may be set to a higher level than the second power voltage VSS.

The third power voltage VREF may be a voltage for initializing the gate of a driving transistor included in the pixel PXij. The third power voltage VREF may be used to achieve a predetermined gradation by using a voltage difference between a data signal and the third power voltage VREF. To facilitate this, the third power voltage VREF may be set to a predetermined value within the voltage range of the data signal.

The fourth power voltage VINT1 may be a voltage for initializing a capacitor included in the pixel PXij. The fourth power voltage VINT1 may be set to a level lower than the third power voltage VREF. For example, the fourth power voltage VINT1 may be set to a value lower than a difference between the third power voltage VREF and a threshold voltage of the driving transistor. However, the embodiment of the inventive concept is not limited thereto.

The fifth power voltage VINT2 may be a voltage for initializing the cathode of the light-emitting element included in the pixel PXij. The fifth power voltage VINT2 may be set to a level lower than the first power voltage VDD or the fourth power voltage VINT1, or may be set to a level similar to or equal to the third power voltage VREF. However, the embodiment of the inventive concept is not limited thereto, and the fifth power voltage VINT2 may be set to a level similar to or equal to the first power voltage VDD.

The sixth power voltage VCOMP may supply a predetermined current to the driving transistor to compensate for the threshold voltage of the driving transistor.

FIG. 1 illustrates that the first to sixth power voltages VDD, VSS, VREF, VINT1, VINT2, and VCOMP are all supplied from the power supply unit PWS, but the embodiment of the inventive concept is not limited thereto. For example, the first power voltage VDD and the second power voltage VSS may be supplied regardless of the structure of the pixel PXij. Additionally, at least one of the third power voltage VREF, the fourth power voltage VINT1, the fifth power voltage VINT2 and the sixth power voltage VCOMP may not be supplied, depending on the structure of the pixel PXij.

In an embodiment of the inventive concept, signal lines connected to the pixel PXij may be configured in various ways depending on the circuit structure of the pixel PXij.

The scan driver SDC may receive a first control signal SCS from the timing controller TC and, in response to the first control signal SCS, supply a scan signal to each of the first scan lines GWL1 to GWLn, the second scan lines GCL1 to GCLn, the third scan lines GIL1 to GILn, the fourth scan lines GBL1 to GBLn, and the fifth scan lines GRL1 to GRLn.

The scan signal may be set to a voltage level that can turn on transistors that receive the scan signal. For example, a scan signal supplied to a P-type transistor may be set to a logic low level, and a scan signal supplied to an N-type transistor may be set to a logic high level. Hereinafter, the expression “a scan signal is supplied” may mean that the scan signal is supplied at a logic level sufficient to activate the transistor controlled by the scan signal.

FIG. 1 illustrates, for the convenience of explanation, that the scan driver SDC is a single element, but the embodiment of the inventive concept is not limited thereto. According to an embodiment of the inventive concept, a plurality of scan drivers may be included to supply a scan signal to each of the first scan lines GWL1 to GWLn, the second scan lines GCL1 to GCLn, the third scan lines GIL1 to GILn, the fourth scan lines GBL1 to GBLn, and the fifth scan lines GRL1 to GRLn.

The light-emitting driver EDC may supply a light-emitting signal to the light-emitting lines ESL1 to ESLn, in response to a second control signal ECS. For example, the light-emitting signal may be sequentially supplied to the light-emitting lines ESL1 to ESLn.

Transistors connected to the light-emitting lines ESL1 to ESLn according to an embodiment of the inventive concept may be composed of N-type transistors. In this case, the light-emitting signal supplied to the light-emitting lines ESL1 to ESLn may be set to a gate-on voltage. Transistors that receive the light-emitting signal may be turned off when the light-emitting signal is supplied. In other cases, the transistors may be configured to remain in a turned-on state.

The second control signal ECS may include a light-emitting start signal and clock signals. The light-emitting driver EDC may be implemented as a shift register which sequentially generates and outputs the light-emitting signal in pulse form by sequentially shifting the light-emitting start signal in pulse form using the clock signals.

The data driver DDC may receive a third control signal DCS and image data RGB from the timing controller TC. The data driver DDC may convert the image data RGB in digital form into an analog data signal (e.g., a data signal). The data driver DDC may supply a data signal to the data lines DL1 to DLm in response to the third control signal DCS.

The third control signal DCS may include a data enable signal, a horizontal start signal, a data clock signal, and other signals that command the output of valid data. For example, the data driver DDC may include a shift register configured to generate a sampling signal by shifting the horizontal start signal in synchronization with the data clock signal, a latch configured to latch the image data RGB in response to the sampling signal, a digital-to-analog converter (or decoder) configured to convert the latched image data (e.g., in digital form) into analog data signal, and buffers (or amplifiers) configured to output the data signals to the data lines DL1 to DLm.

The power supply unit PWS may supply the display panel DP with the first power voltage VDD, the second power voltage VSS, and the third power voltage VREF for driving the pixel PXij. In addition, the power supply unit PWS may supply the display panel DP with at least one of the fourth power voltage VINT1, the fifth power voltage VINT2, or the sixth power voltage VCOMP.

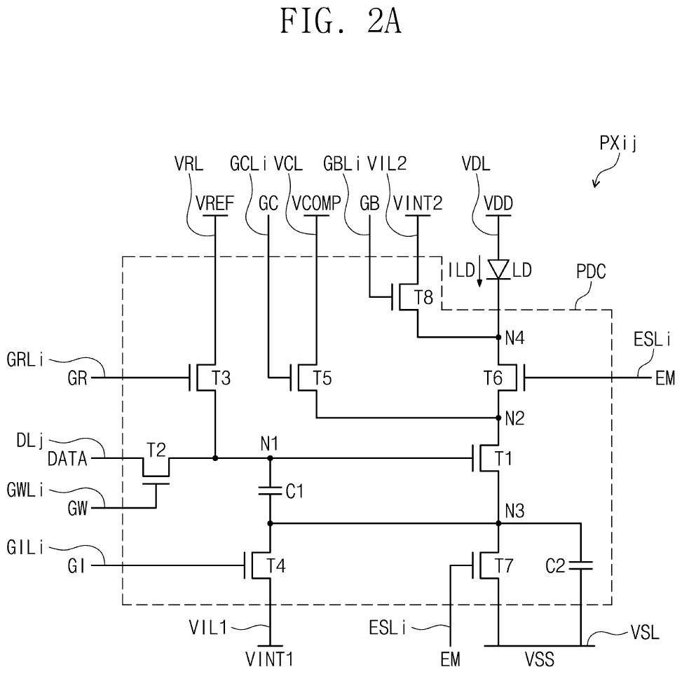

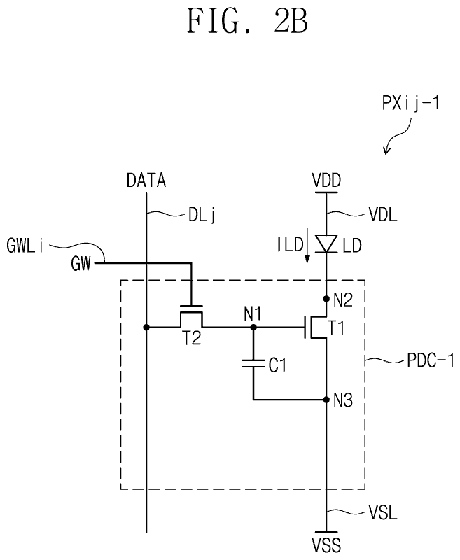

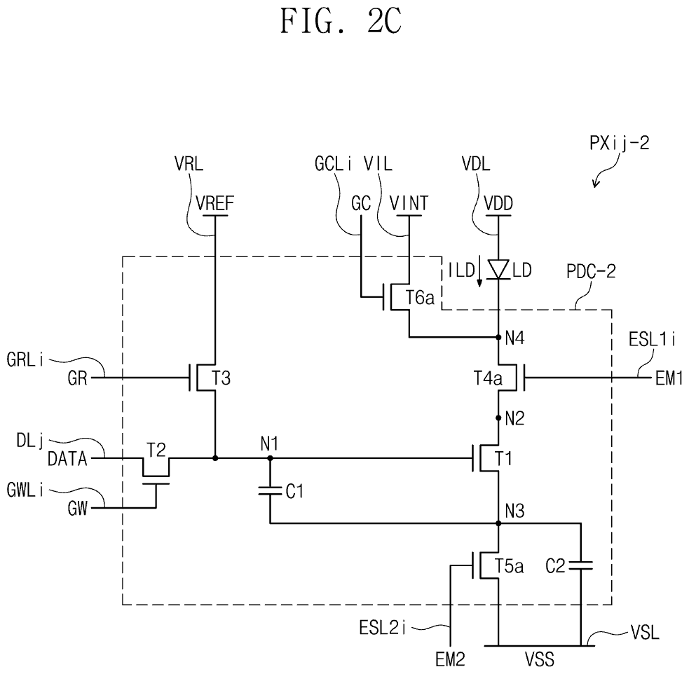

For example, the power supply unit PWS may supply the display panel DP with the first power voltage VDD, the second power voltage VSS, the third power voltage VREF, the fourth power voltage VINT1, the fifth power voltage VINT2, and the sixth power voltage VCOMP, respectively, via a first power line VDL (see FIG. 2A), a second power line VSL (see FIG. 2A), a third power line VRL (or reference voltage line, see FIG. 2A), a fourth power line VIL1 (or first initialization voltage line, see FIG. 2A), a fifth power line VIL2 (or second initialization voltage line, see FIG. 2A), and a sixth power line VCL (or compensation voltage line, see FIG. 2A), which are not illustrated.

The power supply unit PWS may be implemented as a power management integrated circuit, but the embodiment of the inventive concept is not limited thereto.

The timing controller TC may generate the first control signal SCS, the second control signal ECS, the third control signal DCS, and a fourth control signal PCS, based on an input image data IRGB, a sync signal Sync (e.g., a vertical sync signal, a horizontal sync signal, etc.), a data enable signal DE, a clock signal, and the like. The first control signal SCS may be supplied to the scan driver SDC, the second control signal ECS may be supplied to the light-emitting driver EDC, the third control signal DCS may be supplied to the data driver DDC, and the fourth control signal PCS may be supplied to the power supply unit PWS. The timing controller TC may rearrange the input image data IRGB based on the arrangement of the pixels PXij in the display panel DP to generate image data RGB (or frame data).

The scan driver SDC, the light-emitting driver EDC, the data driver DDC, the power supply unit PWS, and/or the timing controller TC may be formed directly in the display panel DP or provided in the form of a separate driving chip and connected to the display panel DP. In addition, at least two of the scan driver SDC, the light-emitting driver EDC, the data driver DDC, the power supply unit PWS, and the timing controller TC may be provided as one driving chip. For example, the data driver DDC and the timing controller TC may be provided as one driving chip.

The electronic device DD according to the embodiment of the inventive concept has been explained with reference to FIG. 1. However, the scope of the inventive concept is not limited to this configuration. Additional signal lines may be included, or certain signal lines may be omitted, depending on the pixel configuration. Furthermore, the connection relationship between a pixel and its signal lines may be modified. If any signal line is omitted, another signal line may serve as a substitute for the omitted one.

FIGS. 2A, 2B, and 2C are equivalent circuit diagrams of pixels according to an embodiment of the inventive concept. As examples, FIGS. 2A, 2B, and 2C respectively illustrate the equivalent circuit diagrams of pixels PXij, PXij-1, and PXij-2 connected to an i-th first scan line GWLi (hereinafter referred to as a write scan line) and a j-th data line DLj (hereinafter referred to as a data line).

As illustrated in FIG. 2A, the pixel PXij includes a light-emitting element LD and a pixel driver PDC. The light-emitting element LD is connected to the first power line VDL and the pixel driver PDC.

The pixel driver PDC may be connected to a plurality of scan lines GWLi, GCLi, GILi, GBLi, and GRLi, the data line DLj, a light-emitting line ESLi, and a plurality of power voltage lines VDL, VSL, VIL1, VIL2, VRL, and VCL. The pixel driver PDC may include first to eighth transistors T1, T2, T3, T4, T5, T6, T7, and T8, a first capacitor C1, and a second capacitor C2. Hereinafter, as an example, all of the first to eighth transistors T1, T2, T3, T4, T5, T6, T7, and T8 will be described as N-type transistors. However, the embodiment of the inventive concept is not limited thereto. Some of the first to eighth transistors T1 to T8 may be N-type transistors, while others may be P-type transistors, or all of the first to eighth transistors T1 to T8 may be P-type transistors.

The gate of the first transistor T1 may be connected to a first node N1. The first electrode of the first transistor T1 may be connected to a second node N2, and the second electrode of the first transistor T1 may be connected to a third node N3. The first transistor T1 may be a driving transistor. The first transistor T1 may control a driving current ILD flowing from the first power line VDL to the second power line VSL via the light-emitting element LD based on a voltage at the first node N1. In this case, the first power voltage VDD may be set to a potential higher than the second power voltage VSS.

In this specification, the expression “a transistor and a signal line, or a transistor and another transistor are electrically connected to each other” means that the source, drain, or gate of a transistor is either integrally formed with the signal line or connected to it via a connection electrode. Similarly, the expression “a transistor and another transistor are electrically connected to each other” may mean that the source, drain, or gate of a transistor is either integrally formed with a portion of the another transistor or connected to it via a connection electrode.

The second transistor T2 may include a gate connected to the write scan line GWLi, a first electrode connected to the data line DLj, and a second electrode connected to the first node N1. The second transistor T2 may supply a data signal DATA to the first node N1 in response to a write scan signal GW transmitted through the write scan line GWLi. When the write scan signal GW is supplied to the write scan line GWLi, the second transistor T2 may be turned on to electrically connect the data line DLj and the first node N1 to each other.

The third transistor T3 may be connected between the first node N1 and the reference voltage line VRL. The first electrode of the third transistor T3 may receive the reference voltage VREF through the reference voltage line VRL, and the second electrode of the third transistor T3 may be connected to the first node N1. In this embodiment, the gate of the third transistor T3 may receive a reset scan signal GR through the i-th fifth scan line GRLi (hereinafter referred to as a reset scan line). When the reset scan signal GR is supplied to the reset scan line GRLi, the third transistor T3 may be turned on to provide the reference voltage VREF to the first node N1.

The fourth transistor T4 may be connected between the third node N3 and the first initialization voltage line VILL. The first electrode of the fourth transistor T4 may be connected to the third node N3, and the second electrode of the fourth transistor T4 may be connected to the first initialization voltage line VIL1 that provides the first initialization voltage VINT1. The fourth transistor T4 may be referred to as a first initialization transistor. The gate of the fourth transistor T4 may receive a first initialization scan signal GI through the i-th third scan line GILi (hereinafter referred to as a first initialization scan line). When the first initialization scan signal GI is supplied to the first initialization scan line GILi, the fourth transistor T4 may be turned on to supply the first initialization voltage VINT1 to the third node N3.

The fifth transistor T5 may be connected between the compensation voltage line VCL and the second node N2. The first electrode of the fifth transistor T5 may receive the compensation voltage VCOMP through the compensation voltage line VCL, and the second electrode of the fifth transistor T5 may be connected to the second node N2 to be electrically connected to the first electrode of the first transistor T1. The gate of the fifth transistor T5 may receive a compensation scan signal GC through the i-th second scan line GCLi (hereinafter referred to as a compensation scan line). When the compensation scan signal GC is supplied to the compensation scan line GCLi, the fifth transistor T5 may be turned on to provide the compensation voltage VCOMP to the second node N2. During this compensation period, a threshold voltage of the first transistor T1 may be adjusted.

The sixth transistor T6 may be connected between the first transistor T1 and the light-emitting element LD. Specifically, the gate of the sixth transistor T6 may receive a light-emitting signal EM through the i-th light-emitting line ESLi (hereinafter referred to as a light-emitting line). The first electrode of the sixth transistor T6 may be connected to the cathode of the light-emitting element LD through a fourth node N4, and the second electrode of the sixth transistor T6 may be connected to the first electrode of the first transistor T1 through the second node N2. The sixth transistor T6 may be referred to as a first light-emitting control transistor. When the light-emitting signal EM is supplied to the light-emitting line ESLi, the sixth transistor T6 may be turned on to electrically connect the light-emitting element LD and the first transistor T1 to each other.

The seventh transistor T7 may be connected between the second power line VSL and the third node N3. The first electrode of the seventh transistor T7 may be connected to the second electrode of the first transistor T1 through the third node N3, and the second electrode of the seventh transistor T7 may receive the second power voltage VSS through the second power line VSL. The gate of the seventh transistor T7 may be electrically connected to the light-emitting line ESLi. The seventh transistor T7 may be referred to as a second light-emitting control transistor. When the light-emitting signal EM is supplied to the light-emitting line ESLi, the seventh transistor T7 may be turned on to electrically connect the second electrode of the first transistor T1 and the second power line VSL to each other.

In this embodiment, the sixth transistor T6 and the seventh transistor T7 are illustrated as being connected to the same light-emitting line ESLi and turned on by the same light-emitting signal EM. However, this is merely an example, and the sixth transistor T6 and the seventh transistor T7 may be independently turned on by different signals. In addition, in the pixel driver PDC according to an embodiment of the inventive concept, any one of the sixth transistor T6 and the seventh transistor T7 may be omitted.

The eighth transistor T8 may be connected between the second initialization voltage line VIL2 and the fourth node N4. In other words, the eighth transistor T8 may include: a gate connected to the i-th fourth scan line GBLi (hereinafter referred to as a second initialization scan line); a first electrode connected to the second initialization voltage line VIL2; and a second electrode connected to the fourth node N4. The eighth transistor T8 may be referred to as a second initialization transistor. The eighth transistor T8 may supply the second initialization voltage VINT2 to the fourth node N4, which is connected to the cathode of the light-emitting element LD, in response to a second initialization scan signal GB transmitted through the second initialization scan line GBLi. The cathode of the light-emitting element LD may be initialized by the second initialization voltage VINT2.

In this embodiment, some of the second to eighth transistors T2, T3, T4, T5, T6, T7, and T8 may be simultaneously turned on by the same scan signal. For example, the eighth transistor T8 and the fifth transistor T5 may be simultaneously turned on by the same scan signal. For example, the eighth transistor T8 and the fifth transistor T5 may be operated by the same compensation scan signal GC. The eighth transistor T8 and the fifth transistor T5 may be simultaneously turned on/off by the same compensation scan signal GC. In this case, the compensation scan line GCLi and the second initialization scan line GBLi may be provided as a single scan line. Accordingly, the initialization of the cathode of the light-emitting element LD and the compensation of the threshold voltage of the first transistor T1 may be performed at the same time. However, this is just as an example, and the inventive concept is not limited thereto.

In addition, according to this inventive concept, the initialization of the cathode of the light-emitting element LD and the compensation of the threshold voltage of the first transistor T1 may be performed by applying the same power voltage. For example, the compensation voltage line VCL and the second initialization voltage line VIL2 may be provided as a single power voltage line. In this case, the initialization operation of the cathode and the compensation operation of the driving transistor may be carried out using a power voltage, simplifying the design of the driver. However, this is merely as an example, and the inventive concept is not restricted to any specific embodiment.

The first capacitor C1 may be disposed between the first node N1 and the third node N3. The first capacitor C1 may store the voltage difference between the first node N1 and the third node N3. The first capacitor C1 may be referred to as a storage capacitor.

The second capacitor C2 may be disposed between the third node N3 and the second power line VSL. In other words, one electrode of the second capacitor C2 may be connected to the second power line VSL that receives the second power voltage VSS, and the other electrode of the second capacitor C2 may be connected to the third node N3. The second capacitor C2 may store a charge corresponding to the voltage difference between the second power voltage VSS and the third node N3. The second capacitor C2 may be referred to as a hold capacitor. The second capacitor C2 may have a greater storage capacity than the first capacitor CL. Accordingly, the second capacitor C2 may minimize voltage changes at the third node N3 in response to voltage fluctuations at the first node N1.

In this embodiment, the light-emitting element LD may be connected to the pixel driver PDC through the fourth node N4. The light-emitting element LD may include an anode connected to the first power line VDL and a cathode opposite to the anode. In this embodiment, the light-emitting element LD may be connected to the pixel driver PDC through the cathode. In other words, in the pixel PXij according to this inventive concept, a connection node where the light-emitting element LD and the pixel driver PDC are connected may be the fourth node N4. The fourth node N4 may correspond to the connection point between the first electrode of the sixth transistor T6 and the cathode of the light-emitting element LD. Accordingly, the potential at the fourth node N4 may substantially correspond to the potential of the cathode of the light-emitting element LD.

Specifically, the anode of the light-emitting element LD may be connected to the first power line VDL so that the first power voltage VDD, which is a constant voltage, is applied. The cathode of the light-emitting element LD may be connected to the first transistor T1 through the sixth transistor T6. In this embodiment, where the first to eighth transistors T1 to T8 are N-type transistors, the potential at the third node N3, corresponding to the source of the first transistor T1, which serves as the driving transistor, may not be directly influenced by the characteristics of the light-emitting element LD. Therefore, even if degradation of the light-emitting element LD occurs, its impact on a gate-source voltage (“Vgs”) of the transistors constituting the pixel driver PDC, particularly the driving transistor, may be minimized. This reduction in the change of the driving current caused by the degradation of the light-emitting element LD may help mitigate afterimage defects on the display panel that arise with extended usage and improve the overall lifespan of the display panel.

Alternatively, as illustrated in FIG. 2B, the pixel PXij-1 may include a pixel driver PDC-1 including two transistors T1 and T2 and one capacitor C1. The pixel driver PDC-1 may be connected to a light-emitting element LD, a write scan line GWLi, a data line DLj, and a second power line VSL. The pixel driver PDC-1 illustrated in FIG. 2B may correspond to the pixel driver PDC illustrated in FIG. 2A, from which the third to eighth transistors T3 to T8 and the second capacitor C2 are omitted.

Each of the first and second transistors T1 and T2 may be an N-type or P-type transistor. In this embodiment, each of the first and second transistors T1 and T2 will be described as an N-type transistor.

The first transistor T1 may include a gate connected to a first node N1, a first electrode connected to a second node N2, and a second electrode connected to a third node N3. The second node N2 may be connected to the first power line VDL side, and the third node N3 may be connected to the second power line VSL side. The first transistor T1 is connected to the light-emitting element LD through the second node N2 and connected to the second power line VSL through the third node N3. The first transistor T1 may be a driving transistor.

The second transistor T2 may include a gate configured to receive a write scan signal GW through the write scan line GWLi, a first electrode connected to the data line DLj, and a second electrode connected to the first node N1. The second transistor T2 may supply a data signal DATA to the first node N1 in response to the write scan signal GW transmitted through the write scan line GWLi.

The first capacitor C1 may include a first electrode connected to the first node N1 and a second electrode connected to the third node N3. The first capacitor C1 may store the data signal DATA transmitted to the first node N1.

The light-emitting element LD may include an anode and a cathode. In this embodiment, the anode of the light-emitting element LD is connected to the first power line VDL, and the cathode of the light-emitting element LD is connected to the pixel driver PDC-1 through the second node N2. In this embodiment, the cathode of the light-emitting element LD may be connected to the first transistor T1. The light-emitting element LD may emit light in response to the amount of current flowing through the first transistor T1 of the pixel driver PDC-1.

In this embodiment, where the first and second transistors T1 and T2 are N-type transistors, the second node N2 to which the cathode of the light-emitting element LD and the pixel driver PDC-1 are connected may correspond to the drain of the first transistor T1. This ensures that changes in the gate-source voltage (“Vgs”) of the first transistor T1 caused by the light-emitting element LD can be prevented. Consequently, the variation in driving current due to degradation of the light-emitting element LD may be minimized. As a result, afterimage defects on the display panel caused by prolonged usage can be reduced, and the lifespan of the display panel may be extended.

Alternatively, as illustrated in FIG. 2C, the pixel PXij-2 may include a pixel driver PDC-2 including six transistors T1, T2, T3, T4a, T5a, and T6a and two capacitors C1 and C2.

The pixel driver PDC-2 may be connected to a light-emitting element LD, a write scan line GWLi, a reset scan line GRLi, a compensation scan line GCLi, an i-th first light-emitting line ESL1i (hereinafter referred to as a first light-emitting line), an i-th second light-emitting line ESL2i (hereinafter referred to as a second light-emitting line), a data line DLj, a first power line VDL, a second power line VSL, a third power line VRL, and an initialization voltage line VIL.

The structure of the pixel driver PDC-2 illustrated in FIG. 2C may be similar to that of the pixel driver PDC illustrated in FIG. 2A, from which the fourth transistor T4 and the fifth transistor T5 are omitted. Since the area of the pixel driver PDC-2 illustrated in FIG. 2C is smaller than that of the pixel driver PDC illustrated in FIG. 2A, achieving high resolution may be easier.

Each of the first to sixth transistors T1, T2, T3, T4a, T5a, and T6a may be an N-type transistor or a P-type transistor. In this embodiment, each of the first to sixth transistors T1, T2, T3, T4a, T5a, and T6a is described as an N-type transistor.

The first transistor T1 may include a gate connected to a first node N1, a first electrode connected to a second node N2, and a second electrode connected to a third node N3. The second node N2 may be connected to the first power line VDL side, and the third node N3 may be connected to the second power line VSL side. The first transistor T1 is connected to the light-emitting element LD through the second node N2 and the second power line VSL through the third node N3. The first transistor T1 may be a driving transistor.

The second transistor T2 may include a gate configured to receive a write scan signal GW through the write scan line GWLi, a first electrode connected to the data line DLj, and a second electrode connected to the first node N1. The second transistor T2 may supply a data signal DATA to the first node N1 in response to the write scan signal GW transmitted through the write scan line GWLi.

The third transistor T3 may be connected between the first node N1 and the reference voltage line VRL. The first electrode of the third transistor T3 may receive a reference voltage VREF through the reference voltage line VRL, and the second electrode of the third transistor T3 may be connected to the first node N1. In this embodiment, the gate of the third transistor T3 may receive a reset scan signal GR through the reset scan line GRLi. When the reset scan signal GR is supplied to the reset scan line GRLi, the third transistor T3 may be turned on to provide the reference voltage VREF to the first node N1.

The fourth transistor T4a may be connected between the first transistor T1 and the light-emitting element LD. Specifically, the gate of the fourth transistor T4a may receive a first light-emitting signal EM1 through the first light-emitting line ESLli. The first electrode of the fourth transistor T4a may be connected to the cathode of the light-emitting element LD through the fourth node N4, and the second electrode of the fourth transistor T4a may be connected to the first electrode of the first transistor T1 through the second node N2. The fourth transistor T4a may be referred to as a first light-emitting control transistor. When the first light-emitting signal EM1 is supplied to the first light-emitting line ESLli, the fourth transistor T4a may be turned on to electrically connect the light-emitting element LD and the first transistor T1 to each other.

The fifth transistor T5a may be connected between the second power line VSL and the third node N3. The first electrode of the fifth transistor T5a may be connected to the second electrode of the first transistor T1 through the third node N3, and the second electrode of the fifth transistor T5a may receive the second power voltage VSS through the second power line VSL. The gate of the fifth transistor T5a may be electrically connected to the second light-emitting line ESL2i. The fifth transistor T5a may be referred to as a second light-emitting control transistor. When a second light-emitting signal EM2 is supplied to the second light-emitting line ESL2i, the fifth transistor T5a is turned on to electrically connect the second electrode of the first transistor T1 and the second power line VSL to each other.

In this embodiment, the fourth transistor T4a and the fifth transistor T5a may be connected to the first and second light-emitting lines ESLli and ESL2i, which are distinct from each other, and may be turned on by the first and second light-emitting signals EM1 and EM2, respectively, which are also distinct. In other words, the fourth transistor T4a and the fifth transistor T5a may be turned on independently of each other. However, this is only an example and the embodiment of the inventive concept is not limited thereto. For example, in an embodiment of the inventive concept, the fourth transistor T4a and the fifth transistor T5a may be connected to the same light-emitting line and controlled by the same light-emitting signal. In addition, in the pixel driver PDC-2 according to an embodiment of the inventive concept, any one of the fourth transistor T4a and the fifth transistor T5a may be omitted.

The sixth transistor T6a may be connected between the initialization voltage line VIL and the fourth node N4. In other words, the sixth transistor T6a may include a gate connected to the compensation scan line GCLi, a first electrode connected to the initialization voltage line VIL, and a second electrode connected to the fourth node N4. The sixth transistor T6a may be referred to as an initialization transistor. The sixth transistor T6a may supply an initialization voltage VINT to the fourth node N4, which is connected to the cathode of the light-emitting element LD, in response to the compensation scan signal GC transmitted through the compensation scan line GCLi. The cathode of the light-emitting element LD may be initialized by the initialization voltage VINT.

The first capacitor C1 may be disposed between the first node N1 and the third node N3. The first capacitor C1 may store a voltage difference between the first node N1 and the third node N3. The first capacitor C1 may be referred to as a storage capacitor.

The second capacitor C2 may be disposed between the third node N3 and the second power line VSL. In other words, one electrode of the second capacitor C2 may be connected to the second power line VSL that receives the second power voltage VSS, and the other electrode of the second capacitor C2 may be connected to the third node N3. The second capacitor C2 may store a charge corresponding to a voltage difference between the second power voltage VSS and the third node N3. The second capacitor C2 may be referred to as a hold capacitor.

The light-emitting element LD may include an anode and a cathode. In this embodiment, the anode of the light-emitting element LD is connected to the first power line VDL, and the cathode of the light-emitting element LD is connected to the pixel driver PDC-2 through the fourth node N4. In this embodiment, the cathode of the light-emitting element LD may be connected to the first transistor T1 through the fourth transistor T4a. The light-emitting element LD may emit light in response to the amount of current flowing through the first transistor T1 of the pixel driver PDC-2.

In this embodiment, where the first to sixth transistors T1, T2, T3, T4a, T5a, and T6a are N-type transistors, the potential at the third node N3, corresponding to the source of the first transistor T1, which functions as a driving transistor, may not be directly influenced by the characteristics of the light-emitting element LD. Accordingly, even if the degradation of the light-emitting element LD occurs, its impact on the gate-source voltage (“Vgs”) of the transistors constituting the pixel driver PDC-2, particularly the driving transistor, may be reduced. As a result, the variation in driving current caused by degradation of the light-emitting element LD may be reduced, thereby mitigating afterimage defects on the display panel due to prolonged usage and improving the display panel's lifespan.

FIGS. 2A, 2B, and 2C illustrate circuits for the pixel drivers PDC, PDC-1, and PDC-2 according to an embodiment of the inventive concept. In the display panel according to an embodiment of the inventive concept, as long as the circuits are connected to the cathode of the light-emitting element LD, the number and arrangement of transistors as well as the number and arrangement capacitors may be configured in various ways.

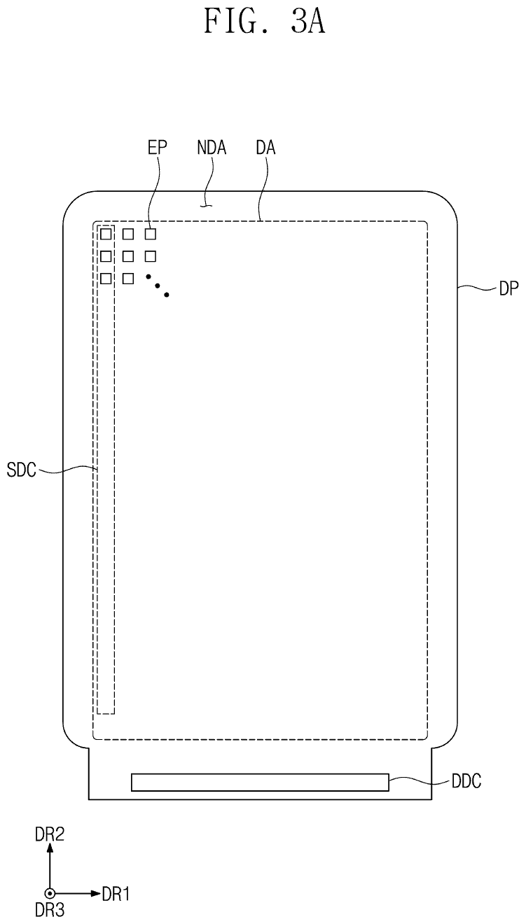

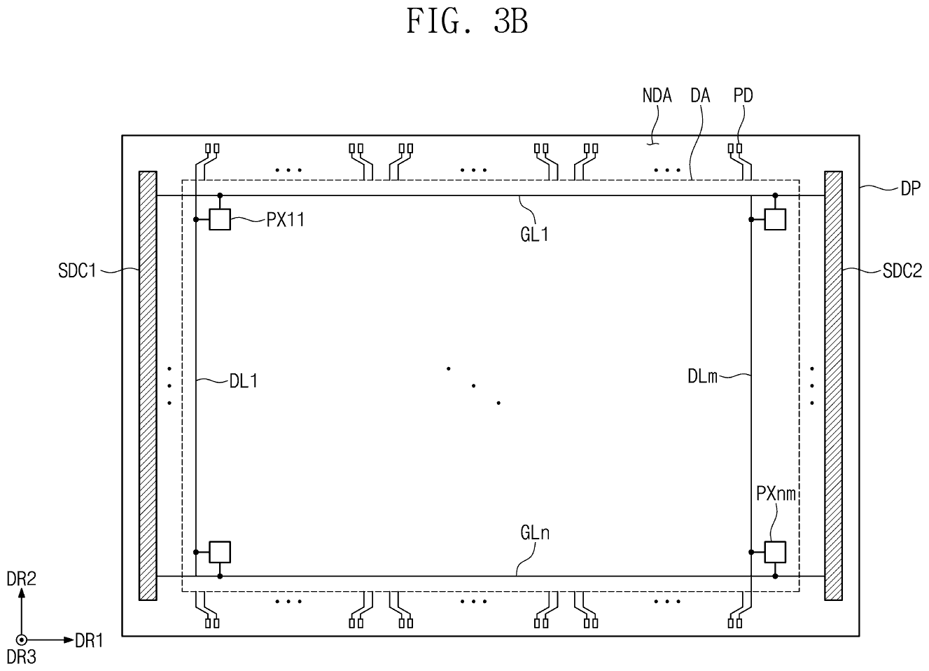

FIGS. 3A and 3B are plan views briefly illustrating a display panel according to an embodiment of the inventive concept. Each of FIGS. 3A and 3B are illustrated with some components omitted. Hereinafter, the inventive concept will be described with reference to FIGS. 3A and 3B.

Referring to FIG. 3A, the display panel DP according to an embodiment of the inventive concept may be divided into a display region DA and a peripheral region NDA (or non-display region). In other words, the display region DA and the peripheral region NDA may be defined in the display panel DP. The display region DA may include a plurality of light-emitting portions EP.

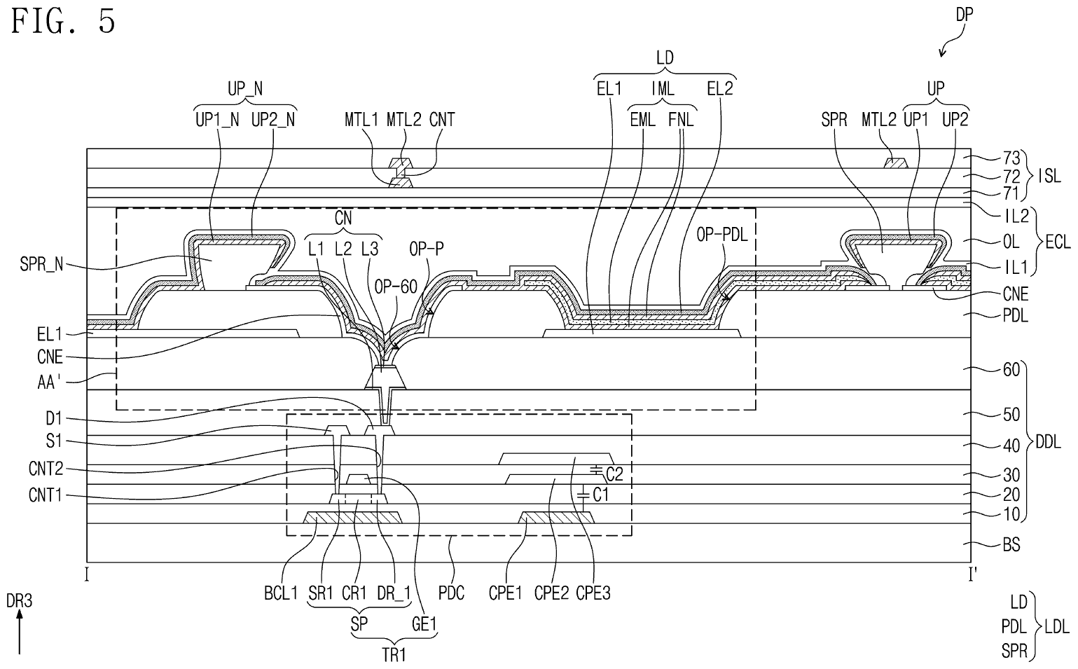

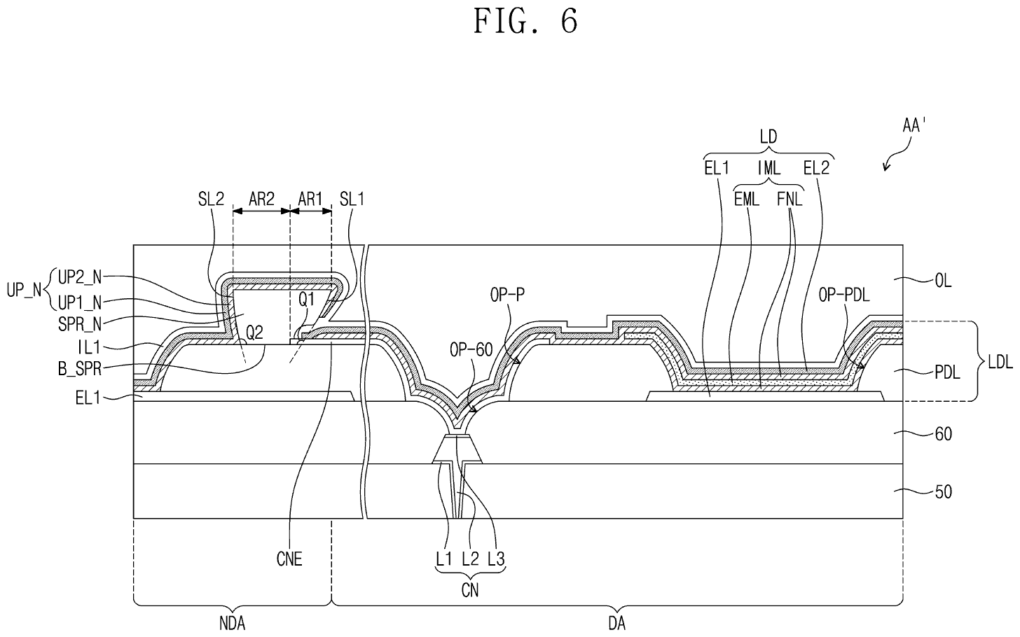

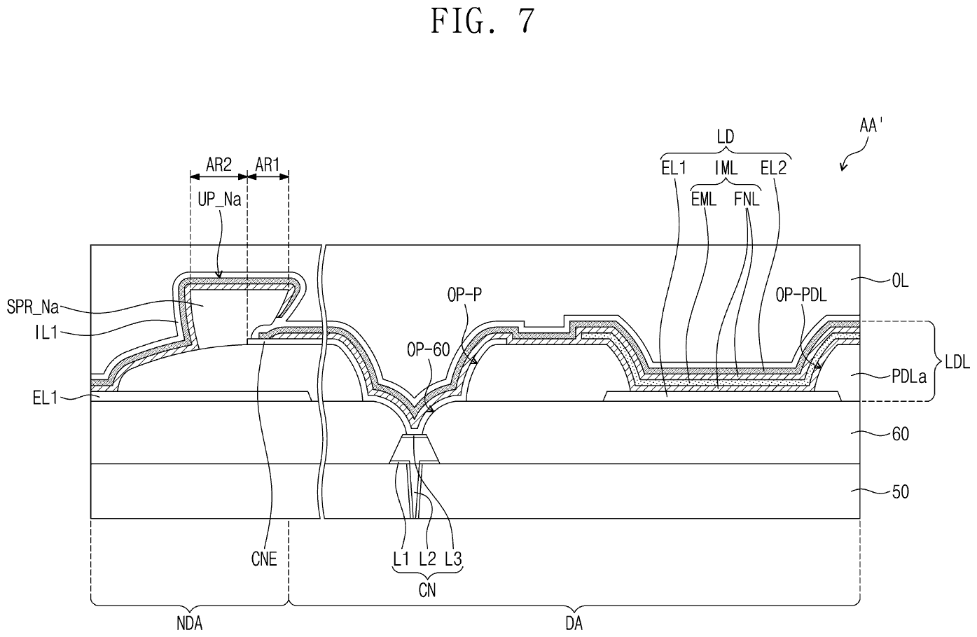

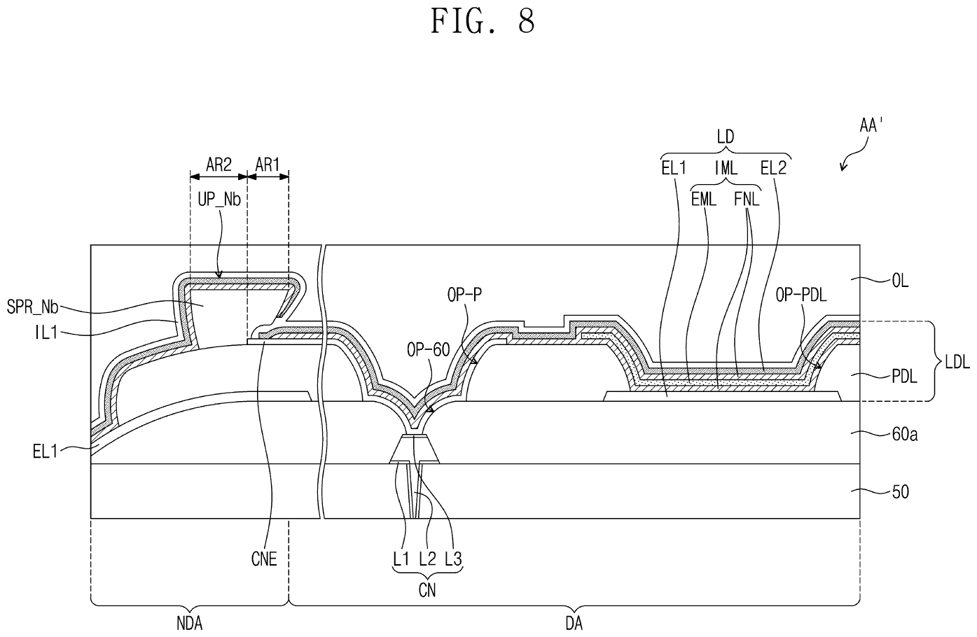

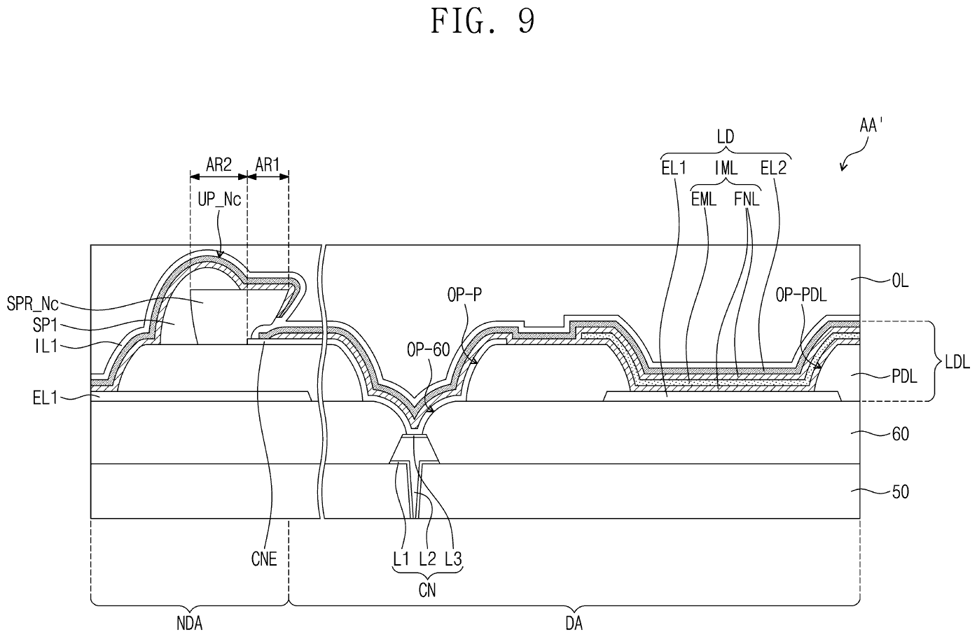

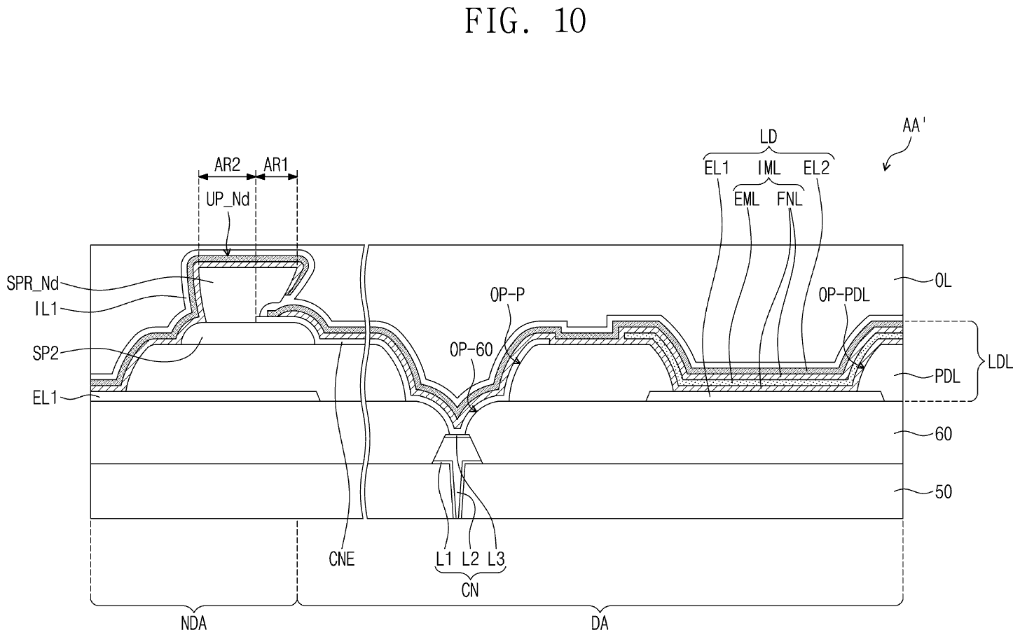

The light-emitting portions EP may be regions where light is emitted by the pixels PXij (see FIG. 1), respectively. Specifically, each of the light-emitting portions EP may correspond to a light-emitting opening OP-PDL (see FIG. 5), which will be described later.

The peripheral region NDA may be adjacent to the display region DA. In this embodiment, the peripheral region NDA is illustrated as surrounding the edge of the display region DA. However, this is just an example, and the peripheral region NDA may be disposed on just one side of the display region DA or may be omitted, and the inventive concept is not limited to any one embodiment.

In this embodiment, a scan driver SDC and a data driver DDC may be mounted on the display panel DP. In an embodiment of the inventive concept, the scan driver SDC may be disposed in the display region DA, and the data driver DDC may be disposed in the peripheral region NDA. On a plane, the scan driver SDC may overlap at least some of the plurality of light-emitting portions EP disposed in the display region DA. Since the scan driver SDC is disposed in the display region DA, the area of the peripheral region NDA may be reduced compared to a typical display panel where the scan driver is disposed in the peripheral region. This configuration facilitates the implementation of an electronic device with a narrow bezel.

Unlike what is illustrated in FIG. 3A, the scan driver SDC may be divided into two separate portions. These two portions may be disposed on opposites sides of the display region DA, with the center of the display region DA interposed therebetween. Alternatively, the scan driver SDC may be divided into more than two portions.

FIG. 3A illustrates an example of a display panel, and the data driver DDC may be disposed in the display region DA. In this case, some of the light-emitting portions EP disposed in the display region DA may overlap the data driver DDC on a plane.

In an embodiment of the inventive concept, the data driver DDC may be provided in the form of a separate driving chip independent of the display panel DP and connected to the display panel DP. However, this is merely an example, and the data driver DDC may be formed in the same process as the scan driver SDC to constitute the display panel DP.

As illustrated in FIG. 3B, the display panel DP may have a shape where the length in the first direction DR1 is greater than the length in the second direction DR2. A plurality of pixels PX11 to PXnm arranged in n rows and m columns are illustrated as being disposed in the display region DA. In this embodiment, the display panel DP may include a plurality of scan drivers SDC1 and SDC2. The scan drivers SDC1 and SDC2 are illustrated as including a first scan driver SDC1 and a second scan driver SDC2 spaced apart from each other in the first direction DR1.

The first scan driver SDC1 may be connected to some of the scan lines GL1 to GLn, and the second scan driver SDC2 may be connected to other scan lines GL1 to GLn. For example, the first scan driver SDC1 may be connected to odd-numbered scan lines among the scan lines GL1 to GLn, and the second scan driver SDC2 may be connected to even-numbered scan lines among the scan lines GL1 to GLn.

FIG. 3B illustrates pads PD of the data lines DL1 to DLm. The pads PD may be formed at ends of the data lines DL1 to DLm. The data lines DL1 to DLm may be connected to the data driver DDC (see FIG. 3A) through the pads PD.

According to this inventive concept, the pads PD may be divided and positioned at locations spaced apart from in the peripheral region NDA with the display region DA interposed therebetween. For example, some of the pads PD may be disposed on the upper side adjacent to the first scan line GL1, and other pads PD may be disposed on the lower side adjacent to the last scan line GLn. In this embodiment, pads PD connected to odd-numbered data lines among the data lines DL1 to DLm may be disposed on the upper side, and pads PD connected to even-numbered data lines among the data lines DL1 to DLm. may be disposed on the lower side.

The display panel DP may further include a plurality of upper data drivers connected to the pads PD disposed on the upper side and/or a plurality of lower data drivers connected to the pads PD disposed on the lower side. However, this is merely an example, and the display panel DP may include one upper data driver connected to the pads PD disposed on the upper side and/or one lower data driver connected to the pads PD disposed on the lower side. In other words, the pads PD according to an embodiment of the inventive concept may be disposed on only one side of the display panel DP and connected to a single data driver.

In addition, as described above in FIG. 3A, in the display panel DP of FIG. 3B, the scan driver and/or the data driver may be disposed in the display region DA, and accordingly, some of the light-emitting portions disposed in the display region DA may overlap the scan driver and/or the data driver on a plane.

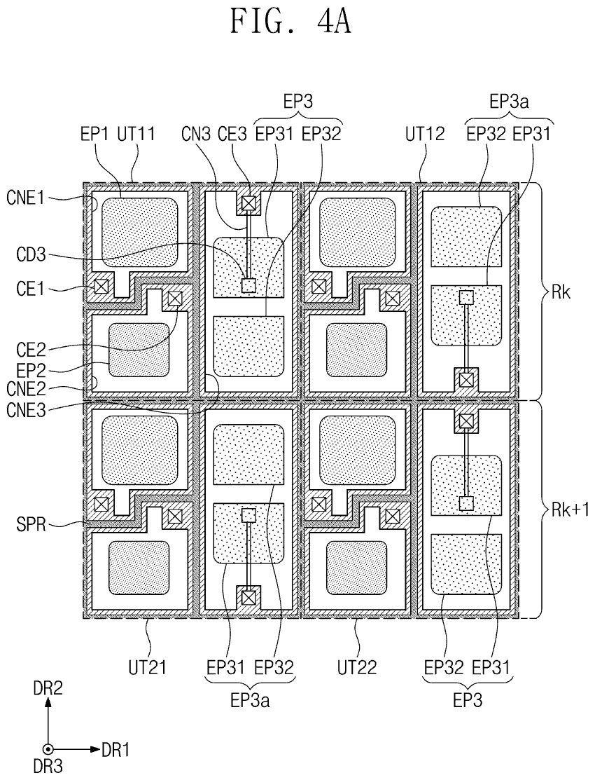

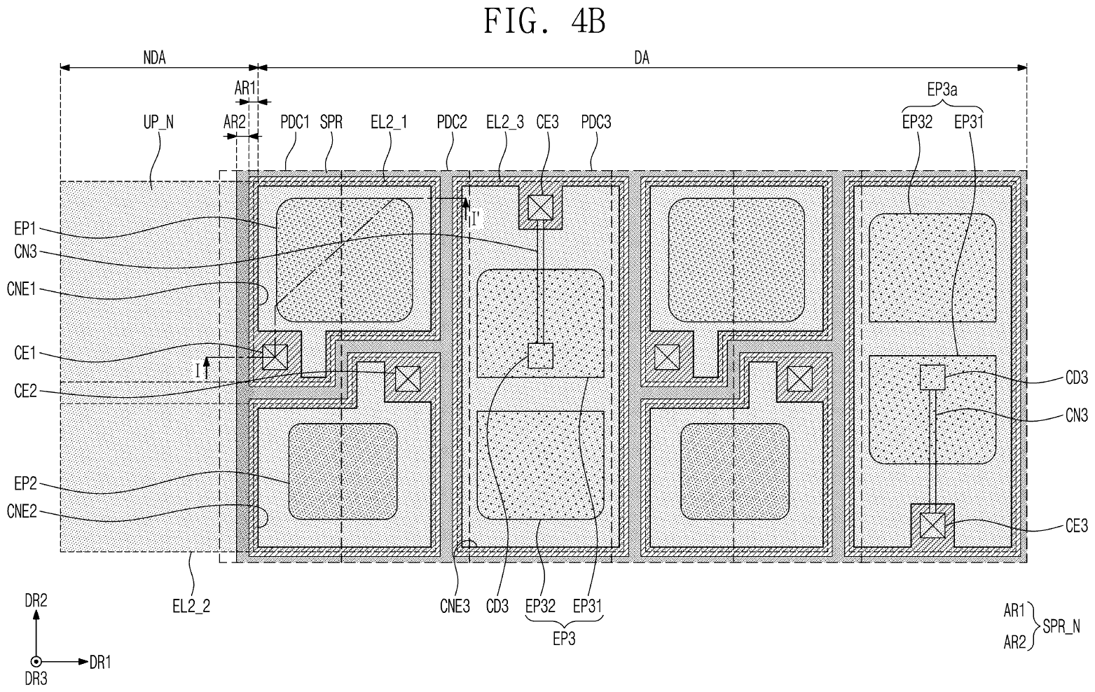

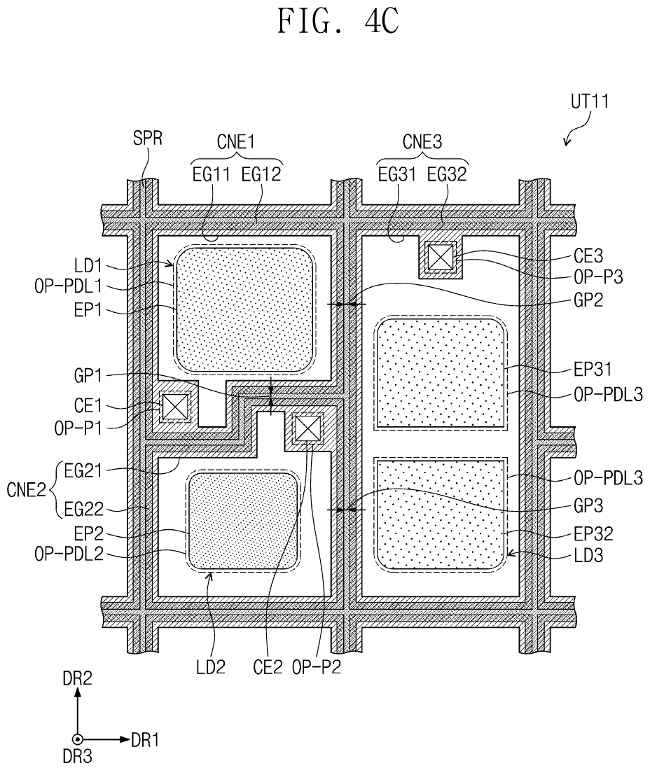

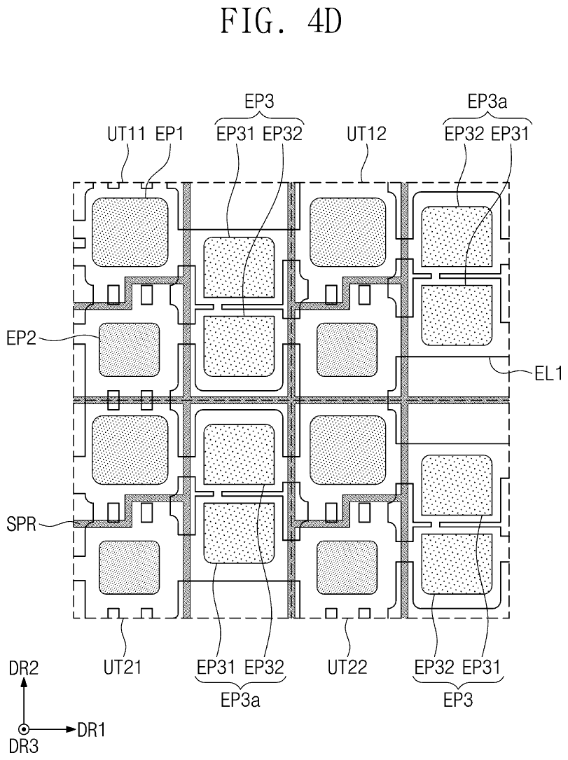

FIGS. 4A to 4D are enlarged plan views of a partial region of the display panel according to an embodiment of the inventive concept.

FIG. 4A illustrates light-emitting units UT11, UT12, UT21, and UT22 in two rows and two columns as an example. Referring to FIG. 4A, the light-emitting portions of a first row Rk include light-emitting portions of the first column light-emitting unit UT11 and second column light-emitting unit UT12, and the light-emitting portions of a second row Rk+1 include light-emitting portions of the first column light-emitting unit UT21 and second column light-emitting unit UT22.

Each of light-emitting portions EP1, EP2, and EP3 may correspond to a light-emitting opening OP-PDL (see FIG. 5) which will be described below. In other words, each of the light-emitting portions EP1, EP2, and EP3 may be a region where light is emitted by the light-emitting element described above. The light-emitting portions EP1, EP2, and EP3 may correspond to a unit that forms an image displayed on the display panel DP (see FIG. 1). More specifically, each of the light-emitting portions EP1, EP2, and EP3 may correspond to a region defined by the light-emitting opening OP-PDL which will be described below, e.g., a region defined by the lower surface of the light-emitting opening OP-PDL.

The light-emitting portions EP1, EP2, and EP3 may include a first light-emitting portion EP1, a second light-emitting portion EP2, and a third light-emitting portion EP3. The first light-emitting portion EP1, the second light-emitting portion EP2, and the third light-emitting portion EP3 may emit light of different colors. For example, the first light-emitting portion EP1 may emit red light, the second light-emitting portion EP2 may emit green light, and the third light-emitting portion EP3 may emit blue light, but the combination of colors is not limited thereto. In addition, at least two of the light-emitting portions EP1, EP2, and EP3 may emit light of the same color. For example, all of the first to third light-emitting portions EP1, EP2, and EP3 may emit blue light or white light.

Among the first to third light-emitting portions EP1, EP2, and EP3, the third light-emitting portion EP3 that displays light emitted by the third light-emitting element may include two sub-light-emitting portions EP31 and EP32 spaced apart from each other in the second direction DR2. However, this is merely an example, and the third light-emitting portion EP3 may be provided as a single pattern having an integrated shape like the first and second light-emitting portions EP1 and EP2. Additionally, at least any one of the first and second light-emitting portions EP1 and EP2 may include sub-light-emitting portions spaced apart from each other.

The light-emitting portions of the first row Rk may include first to third light-emitting portions EP1, EP2, and EP3 of the first column light-emitting unit UT11 and first to third light-emitting portions EP1, EP2, and EP3a of the second column light-emitting unit UT12. The light-emitting portions of the second row Rk+1 may include first to third light-emitting portions EP1, EP2, and EP3a of the first column light-emitting unit UT21 and first to third light-emitting portions EP1, EP2, and EP3 of the second column light-emitting unit UT22.

In an embodiment of the inventive concept, the shapes of the light-emitting portions constituting the first column light-emitting unit UT11 and the light-emitting portions constituting the second column light-emitting unit UT22 may be substantially the same as each other. In addition, the shapes of the light-emitting portions constituting the second column light-emitting unit UT12 and the shapes of the light-emitting portions constituting the first column light-emitting unit UT21 may be substantially the same as each other. The shapes of the light-emitting portions constituting the first column light-emitting unit UT11 may be different from the shapes of the light-emitting portions constituting the second column light-emitting unit UT12. For example, some of the light-emitting portions of the first row Rk and some of the light-emitting portions of the second row Rk+1 may have shapes symmetrical to each other.

In an embodiment of the inventive concept, the third light-emitting portion EP3a of first column light-emitting unit UT21 and the third light-emitting portion EP3 of the first column light-emitting unit UT11 may have a line-symmetrical shape and arrangement relative to an axis parallel to the first direction DR1. In addition, the third light-emitting portion EP3 of the second column light-emitting unit UT22 and the third light-emitting portion EP3a of the second column light-emitting unit UT12 may have a line-symmetrical shape and arrangement relative to an axis parallel to the first direction DR1. However, this is an example and the embodiment of the inventive concept is not limited thereto.

FIG. 4B illustrates light-emitting portions arranged in one row. For ease of explanation, FIG. 4B illustrates a plurality of second electrodes EL2_1, EL2_2, and EL2_3, a plurality of pixel drivers PDC1, PDC2, and PDC3, first to third connection electrodes CNE1, CNE2, and CNE3, a first separator SPR, and a second separator SPR_N.

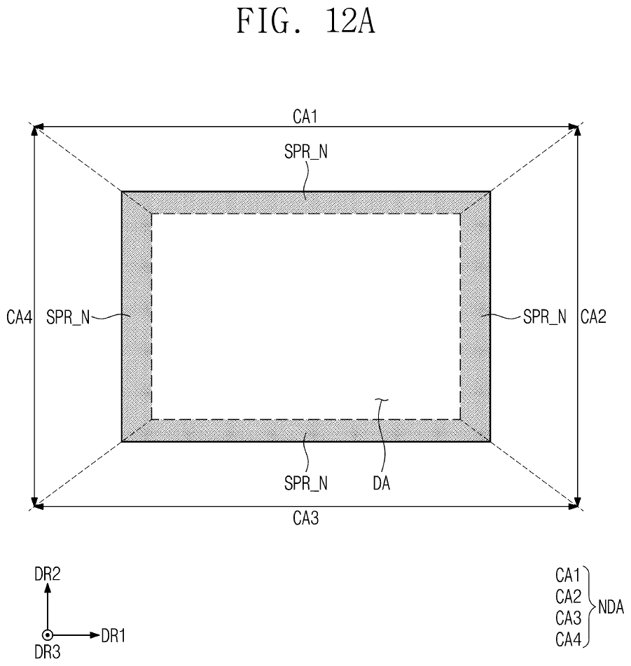

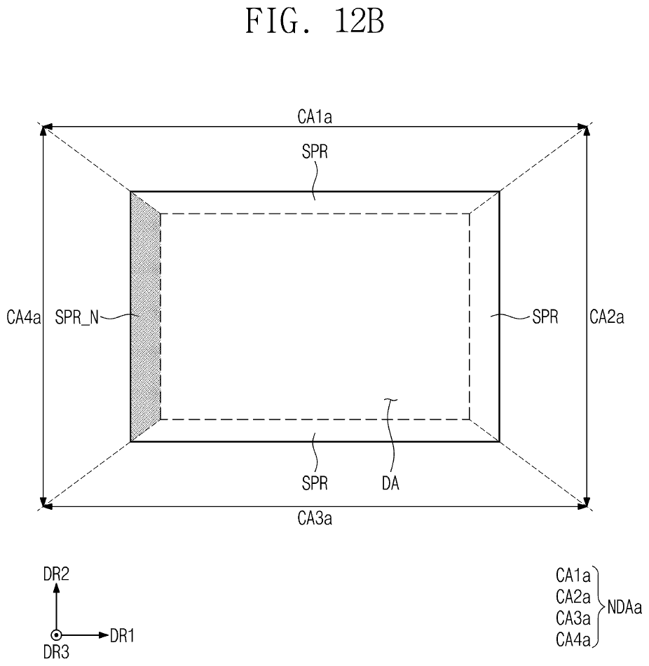

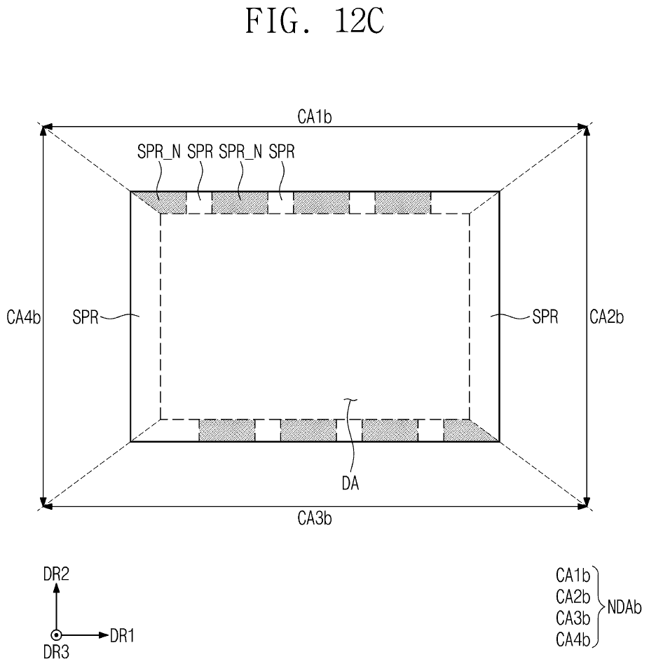

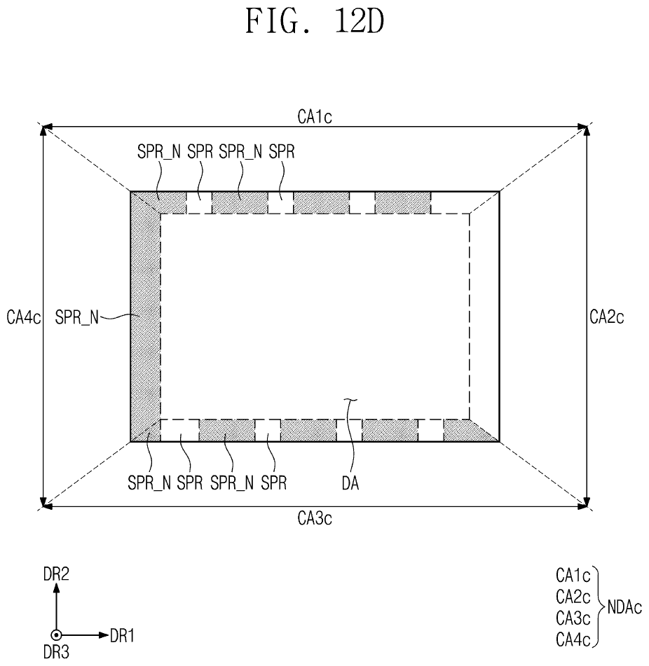

Referring to FIG. 4B, a plurality of separators may be provided. The separators SPR and SPR_N may be disposed on a pixel definition layer PDL (see FIG. 5) and protrude in the thickness direction (e.g., a third direction DR3) of a driving element layer DDL (see FIG. 5). The separators SPR and SPR_N may include first separators SPR disposed in the display region DA or the peripheral region NDA and second separators SPR_N disposed in the peripheral region NDA. In other words, only the first separators SPR may be disposed in the display region DA, and the first separators SPR and/or the second separators SPR_N may be disposed in the peripheral region NDA. Details will be described later in FIGS. 12A to 12D.

The second separators SPR_N may include a first region AR1 that overlaps a connection electrode CNE1, CNE2, or CNE3 on a plane, and a second region AR2 that does not overlap a connection electrode CNE1, CNE2, or CNE3 on a plane. The first region AR1 and the second region AR2 may overlap the peripheral region NDA.

An intermediate layer IML (see FIG. 5) and the second electrodes EL2_1, EL2_2, and EL2_3 may be separated and electrically disconnected by the first separator SPR. The intermediate layer IML and the second electrodes EL2_1, EL2_2, and EL2_3 adjacent to the first region AR1 of the second separators SPR_N may be separated and electrically disconnected by the second separators SPR_N.

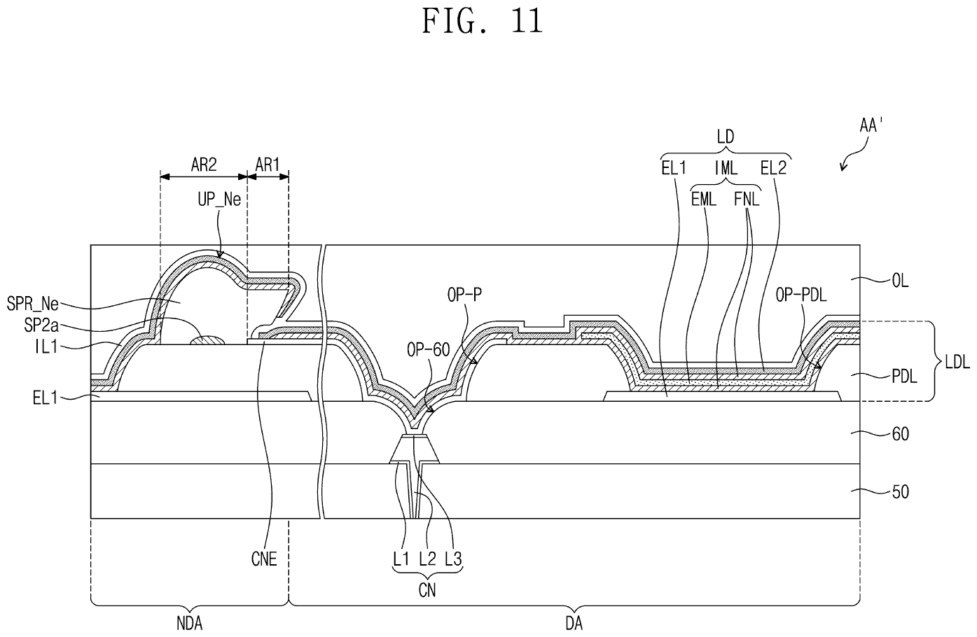

The display panel DP may further include a dummy layer UP (see FIG. 5) disposed on the first separator SPR and an outer dummy layer UP_N disposed on the second separators SPR_N. In a cross-sectional view of FIG. 5, the dummy layer UP and the outer dummy layer UP_N are illustrated as being disconnected from each other, but referring to FIGS. 4A to 4D, the dummy layer UP and the outer dummy layer UP_N may be connected to each other. The outer dummy layer UP_N may extend toward the peripheral region NDA and be electrically connected to the first electrode EL1 (see FIG. 5) in the peripheral region NDA. The outer dummy layer UP_N may include the same material as the intermediate layer IML (see FIG. 5) and the second electrodes EL2_1, EL2_2, or EL2_3, and they may be formed through the same process as each other. For example, the outer dummy layer UP_N may be formed to be separated from the intermediate layer IML and the second electrodes EL2_1, EL2_2, or EL2_3 by the second separator SPR_N. Details will be described later in FIGS. 5 and 6.

FIG. 4C illustrates a first separator SPR, a plurality of light-emitting portions EP1, EP2, and EP3 disposed within a region divided by the first separator SPR, and a plurality of connection electrodes CNE1, CNE2, and CNE3 among the components of the display panel.

Referring to FIGS. 4B and 4C, in this embodiment, one light-emitting unit UT11 may include three light-emitting portions EP1, EP2, and EP3. Accordingly, the light-emitting unit UT11 may include three second electrodes EL2_1, EL2_2, and EL2_3 (hereinafter referred to as first to third cathodes), three pixel drivers PDC1, PDC2, and PDC3, and three connection electrodes CNE1, CNE2, and CNE3. However, this is merely an example, and the number and arrangement of the light-emitting portions included in the light-emitting unit UT11 may be designed in various ways.

The first to third pixel drivers PDC1, PDC2, and PDC3 are respectively electrically connected to the first to third light-emitting elements LD1, LD2, and LD3 including the first to third light-emitting portions EP1, EP2, and EP3. In this specification, the expression “being connected” includes not only being physically connected by a direct contact, but also being electrically connected.

In addition, as illustrated in FIG. 4B, each region where the first to third pixel drivers PDC1, PDC2, and PDC3 are defined on a plane may correspond to a unit where the transistor and capacitor elements constituting the pixel driver PDC (see FIG. 2A) for driving the light-emitting element of a pixel are repeatedly arranged.

The first to third pixel drivers PDC1, PDC2, and PDC3 may be sequentially disposed along the first direction DR1. It is to understood, however, that the arrangement positions of the first to third pixel drivers PDC1, PDC2, and PDC3 may be designed independently, regardless of the positions or shapes of the first to third light-emitting portions EP1, EP2, and EP3.

For example, the first to third pixel drivers PDC1, PDC2, and PDC3 may be positioned outside the regions defined by the separators SPR and SPR_N, e.g., in locations different from where the first to third cathodes EL2_1, EL2_2, and EL2_3 are located. Alternatively, they may be designed with shapes and areas distinct from those of the first to third cathodes EL2_1, EL2_2, and EL2_3. Conversely, the first to third pixel drivers PDC1, PDC2, and PDC3 may also be arranged to overlap the positions of the first to third light-emitting portions EP1, EP2, and EP3, and their shapes and areas may correspond to the regions defined by the separators SPR and SPR_N, such as the first to third cathodes EL2_1, EL2_2, and EL2_3.

In this embodiment, each of the first to third pixel drivers PDC1, PDC2, and PDC3 is illustrated as a rectangular shape. The first to third light-emitting portions EP1, EP2, and EP3 are arranged in shapes that differ from the pixel drivers and have smaller areas. Additionally, the first to third cathodes EL2_1, EL2_2, and EL2_3 are illustrated as atypical shapes, designed to overlap the first to third light-emitting portions EP1, EP2, and EP3.

Accordingly, as illustrated in FIG. 4B, the first pixel driver PDC1 may be disposed in a position overlapping the first light-emitting portion EP1, the second light-emitting portion EP2, and a portion of another adjacent light-emitting unit. The second pixel driver PDC2 may be disposed in a position overlapping the first light-emitting portion EP1, the second light-emitting portion EP2, and the third cathode EL2_3. The third pixel driver PDC3 may be disposed in a position overlapping the third light-emitting portion EP3. It is to be understood that this is provided as an example, and the positions of the first to third pixel drivers PDC1, PDC2, and PDC3 may be designed in various shapes and arrangements, independent of the first to third light-emitting portions EP1, EP2, and EP3.

The light-emitting unit UT11 may include first to third connection electrodes CNE1, CNE2, and CNE3. The first connection electrode CNE1 may electrically connect the first pixel driver PDC1 to the first light-emitting element LD1 to forms or define the first light-emitting portion EP1. Similarly, the second connection electrode CNE2 may electrically connect the second pixel driver PDC2 to the second light-emitting element LD2, forming the second light-emitting portion EP2. The third connection electrode CNE3 may electrically connect the third pixel driver PDC3 to the third light-emitting element LD3, forming the third light-emitting portion EP3. Each of the first to third light-emitting elements LD1, LD2, and LD3 may include a first electrode EL1, an intermediate layer IML disposed on the first electrode EL1, and a second electrode EL2 disposed on the intermediate layer IML.

Specifically, the first to third connection electrodes CNE1, CNE2, and CNE3 may electrically connect the first to third cathodes EL2_1, EL2_2, and EL2_3 to the first to third pixel drivers PDC1, PDC2, and PDC3, respectively, in a one-to-one correspondence. For example, the first connection electrode CNE1 may be electrically connected to the first pixel driver PDC1 and the first cathode EL2_1, the second connection electrode CNE2 may be electrically connected to the second pixel driver PDC2 and the second cathode EL2_2, and the third connection electrode CNE3 may be electrically connected to the third pixel driver PDC3 and the third cathode EL2_3.

Each of the first to third connection electrodes CNE1, CNE2, and CNE3 may be disposed on a pixel definition layer PDL (see FIG. 5) to be described later. The first to third connection electrodes CNE1, CNE2, and CNE3 may have a ring shape that surrounds the corresponding first to third light-emitting portions EP1, EP2, and EP3. In an embodiment of the inventive concept, each of the first to third connection electrodes CNE1, CNE2, and CNE3 is illustrated as having a closed-line ring shape. However, the inventive concept is not limited to this configuration. For example, at least some of the first to third connection electrodes CNE1, CNE2, and CNE3 may have an open or broken ring shape.

The ring shape of the first to third connection electrodes CNE1, CNE2, and CNE3 may increase the flexibility in determining the connection positions between the first to third connection electrodes CNE1, CNE2, and CNE3 and the first to third pixel drivers PDC1, PDC2, and PDC3. For example, the first connection electrode CNE1 may be connected to the first pixel driver PDC1 through a first connection portion CE1, the second connection electrode CNE2 may be connected to the second pixel driver PDC2 through a second connection portion CE2, and the third connection electrode CNE3 may be connected to the third pixel driver PDC3 through a connection line CN3. In other words, additional connection lines linked to the first and second connection electrodes CNE1 and CNE2 may be omitted.

One connection line CN3 may electrically connect the third pixel driver PDC3 and the third light-emitting element LD3 constituting the third light-emitting portion EP3 to each other. Specifically, the connection line CN3 may correspond to a node (see the fourth node N4 of FIG. 2A, the second node N2 of FIG. 2B, or the fourth node N4 of FIG. 2C) through which the light-emitting element LD (see FIG. 2A) is connected to the pixel driver PDC (see FIG. 2A), PDC-1 (see FIG. 2B), or PDC-2 (see FIG. 2C).

The connection line CN3 may include a third connection portion CE3 and a driving connection portion CD3. The third connection portion CE3 may be provided on a first side of the connection line CN3, and the driving connecting portion CD3 may be provided on a second side of the connection line CN3.

The driving connection portion CD3 may be a portion of the connection line CN3 which is connected to the third pixel driver PDC3. In this embodiment, the driving connection portion CD3 may be connected to one electrode of a transistor constituting the third pixel driver PDC3. Specifically, the driving connection portion CD3 may be connected to the drain of the sixth transistor T6 illustrated in FIG. 2A, the drain of the first transistor T1 illustrated in FIG. 2B, or the drain of the fourth transistor T4a illustrated in FIG. 2C. Accordingly, the position of the driving connection portion CD3 may correspond to the position of a transistor physically connected to the connection line CN3 of the pixel driver. The third connection portion CE3 may be a portion of the connection line CN3 which is connected to the third light-emitting element LD3. In this embodiment, the third connection portion CE3 may be connected to the third connection electrode CNE3.

The first connection electrode CNE1 may include a first edge EG11 surrounding at least a portion of the first light-emitting portion EP1 and a second edge EG12 surrounding the first edge EG11. The second connection electrode CNE2 may include a first edge EG21 surrounding at least a portion of the second light-emitting portion EP2 and a second edge EG22 surrounding the first edge EG21. The third connection electrode CNE3 may include a first edge EG31 surrounding at least a portion of the third light-emitting portion EP3 and a second edge EG32 surrounding the first edge EG31.

The first to third connection electrodes CNE1, CNE2, and CNE3 may be spaced apart from each other. For example, gaps GP1, GP2, and GP3 between adjacent connection electrodes among the first to third connection electrodes CNE1, CNE2, and CNE3 may overlap the separators SPR and SPR_N. For example, the gap GP1 may be provided between the first and second connection electrodes CNE1 and CNE2, the gap GP2 may be provided between the first and third connection electrodes CNE1 and CNE3, and the gap GP3 may be provided between the second and third connection electrodes CNE2 and CNE3. For example, the first edges EG11, EG21, and EG31 of the first to third connection electrodes CNE1, CNE2, and CNE3 may not be covered by the separators SPR and SPR_N, but the second edges EG12, EG22, and EG32 of the first to third connection electrodes CNE1, CNE2, and CNE3 may overlap the separators SPR and SPR_N. Alternatively, the second edges EG12, EG22, and EG32 of the first to third connection electrodes CNE1, CNE2, and CNE3 may be covered by the separators SPR and SPR_N.

In an embodiment of the inventive concept, the first to third connection portions CE1, CE2, and CE3 may be disposed where they do not overlap the first to third light-emitting portions EP1, EP2, and EP3 on a plane. For example, a light-emitting opening OP-PDL (see FIG. 5) and through holes OP-P (see FIG. 5) spaced apart from the light-emitting opening OP-PDL may be defined in the pixel definition layer PDL.

The through holes OP-P may include a first through hole OP-P1, a second through hole OP-P2, and a third through hole OP-P3. The first to third connection portions CE1, CE2, and CE3 may be arranged to respectively correspond to the first to third through holes OP-P1, OP-P2, and OP-P3. The light-emitting opening OP-PDL may include a first light-emitting opening OP-PDL1, a second light-emitting opening OP-PDL2, and a third light-emitting opening OP-PDL3. The first to third light-emitting portions EP1, EP2, and EP3 may be defined to respectively correspond to the first to third light-emitting openings OP-PDL1, OP-PDL2, and OP-PDL3. Accordingly, the first to third connection portions CE1, CE2, and CE3 may be spaced apart from the first to third light-emitting portions EP1, EP2, and EP3.

The first to third connection electrodes CNE1, CNE2, and CNE3 may be disposed on the pixel definition layer PDL (see FIG. 5). When viewed on a plane, the first connection electrode CNE1 may surround the first light-emitting opening OP-PDL1, the second connection electrode CNE2 may surround the second light-emitting opening OP-PDL2, and the third connection electrode CNE3 may surround the third light-emitting openings OP-PDL3.

According to an embodiment of the inventive concept, the driving connection portion CD3, where the connection line CN3 is connected to a transistor TR1 (see FIG. 5) of the third pixel driver PDC3, may be located in a position that does not overlap the third connection portion CE3 on a plane. Additionally, the driving connection portion CD3 may overlap the third light-emitting portion EP3. By connecting the third cathode EL2_3 to the third pixel driver PDC3 through the connection line CN3, restrictions on the position or shape of the third light-emitting portion EP3 in the design of the third pixel driver PDC3 may be reduced, thereby increasing the flexibility of the design.

The first to third cathodes EL2_1, EL2_2, and EL2_3 may be connected to the first to third connection electrodes CNE1, CNE2, and CNE3. For example, the lower surfaces of the first to third cathodes EL2_1, EL2_2, and EL2_3 may be respectively connected to (or in contact with) the upper surfaces of the first to third connection electrodes CNE1, CNE2, and CNE3. Accordingly, the contact reliability (or connection stability) between the first to third cathodes EL2_1, EL2_2, and EL2_3 and the first to third connection electrodes CNE1, CNE2, and CNE3 may be further improved.

In addition, the connection regions where the first to third cathodes EL2_1, EL2_2, and EL2_3 and the first to third connection electrodes CNE1, CNE2, and CNE3 are connected may respectively surround at least portions of the first to third light-emitting openings OP-PDL1, OP-PDL2, and OP-PDL3. The first to third cathodes EL2_1, EL2_2, and EL2_3 and the first to third connection electrodes CNE1, CNE2, and CNE3 may be connected to each other in regions adjacent to the separators SPR and SPR_N, with the contact regions defined near the separators SPR and SPR_N. In other words, the first to third cathodes EL2_1, EL2_2, and EL2_3 and the first to third connection electrodes CNE1, CNE2, and CNE3 may not be connected at specific points but rather over relatively wide regions. These regions may correspond to the shapes of the first to third connection electrodes CNE1, CNE2, and CNE3. By increasing the contact region areas, the connections can maintained more stably.

FIG. 4D illustrates a first separator SPR, light-emitting portions EP1, EP2, and EP3, and a first electrode EL1.

Referring to FIG. 4D, the first electrode EL1 (hereinafter referred to as an anode) of the light-emitting element LD (see FIG. 5) according to an embodiment of the inventive concept may be provided in common to the first to third light-emitting portions EP1, EP2, and EP3. In other words, the anode EL1 may be formed as one integrated layer in the entire display region DA, and accordingly, the anode EL1 layer may overlap the first separator SPR. Alternatively, the anodes EL1 of the light-emitting elements LD may be formed as independent conductive patterns, which are spaced apart from each other, and may be electrically connected to each other through other conductive layers, and accordingly, the anode EL1 patterns may not overlap the first separator SPR.

As described above, the first power voltage VDD (see FIG. 2A) may be applied to the anode EL1, and a common voltage may be provided to all of the light-emitting elements. The anode EL1 may be connected to the first power line VDL (see FIG. 2A) that provides the first power voltage VDD in the peripheral region NDA, or may be connected to the first power line VDL (see FIG. 2A) in the display region DA.

A plurality of openings may be defined in the anode EL1 according to this embodiment, and the openings may pass through the anode EL1 layer. The openings in the anode EL1 layer may not overlap the light-emitting portions EP (see FIG. 3A) and may generally overlap the first separator SPR. The openings may facilitate the discharge of gas generated from an organic layer disposed below the anode EL1, for example, a sixth insulating layer 60 (see FIG. 5) described below. Accordingly, during the manufacturing process of the display panel, the gas from the organic layer beneath the light-emitting element may be sufficiently released. Furthermore, the amount of gas discharged from the organic layer after manufacturing may be reduced, thereby decreasing the rate of degradation of the light-emitting element.

FIG. 5 is a cross-sectional view of the display panel DP according to an embodiment of the inventive concept. FIG. 5 is a cross-sectional view illustrating a portion that corresponds to line I-I′ of FIG. 4B.

Referring to FIG. 5, the display panel DP according to an embodiment of the inventive concept may include a base layer BS, a driving element layer DDL, a light-emitting element layer LDL, an encapsulation layer ECL, and a sensing layer ISL. However, this is only an example, and in an embodiment of the inventive concept, the display panel DP may not include the sensing layer ISL.

The driving element layer DDL may include a plurality of insulating layers 10, 20, 30, 40, 50, and 60 disposed on the base layer BS and a plurality of conductive patterns and semiconductor patterns disposed between the insulating layers 10, 20, 30, 40, 50, and 60. The conductive patterns and the semiconductor patterns may be disposed between the insulating layers 10, 20, 30, 40, 50, and 60 to form a pixel driver PDC. For ease of explanation, FIG. 5 illustrates a cross section of one of the regions, where one light-emitting portion is disposed.

The base layer BS may be a member configured to provide a base surface on which the pixel driver PDC is disposed. The base layer BS may be a rigid substrate or a flexible substrate capable of being bent, folded, or rolled. The base layer BS may be a glass substrate, a metal substrate, or a polymer substrate. However, the embodiment of the inventive concept is not limited thereto, and the base layer BS may be an inorganic layer, an organic layer, or a composite material layer.

The base layer BS may have a multi-layer structure. The base layer BS may include a first polymer resin layer, a silicon oxide (SiOx) layer disposed on the first polymer resin layer, an amorphous silicon (a-Si) layer disposed on the silicon oxide layer, and a second polymer resin layer disposed on the amorphous silicon layer. The silicon oxide layer and the amorphous silicon layer may be referred to as a base barrier layer.

The polymer resin layer may include a polyimide-based resin. In addition, the polymer resin layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. In this specification, a “˜˜”-based resin means to include a functional group of “˜˜”.

Each of insulating layers, conductive layers, and semiconductor layers disposed on the base layer BS may be formed by coating, deposition, or the like. Hereafter, the insulating layer, the semiconductor layer, and the conductive layer may be selectively patterned through a plurality of photolithography processes to form a hole in the insulating layer, or a semiconductor pattern, a conductive pattern, a signal line, and the like may be formed.

The driving element layer DDL may include first to sixth insulating layers 10, 20, 30, 40, 50, and 60 sequentially stacked on the base layer BS and a pixel driver PDC. FIG. 5 illustrates one transistor TR1 and two capacitors C1 and C2 of the pixel driver PDC.

The transistor TR1 may correspond to a transistor connected to the light-emitting element LD through an intermediate connection electrode CN and a connection electrode CNE. For example, the transistor TR1 may be a connection transistor connected to a node (the fourth node N4 of FIG. 2A, the second node N2 of FIG. 2B, or the fourth node N4 of FIG. 2C) corresponding to the cathode of the light-emitting element LD, and more specifically, the transistor TR1 may correspond to the sixth transistor T6 of FIG. 2A, the first transistor T1 of FIG. 2B, or the fourth transistor T4a of FIG. 2C. It is to be understood that other transistors constituting the pixel driver PDC may have the same structure as the transistor TR1 (hereinafter referred to as a connection transistor) illustrated in FIG. 5. However, this is merely an example, and the other transistors constituting the pixel driver PDC may have a structure different from that of the connection transistor TR1.

The first insulating layer 10 may be disposed on the base layer BS. The first insulating layer 10 may be an inorganic layer and/or an organic layer and have a single-layer or multi-layer structure. The first insulating layer 10 may include at least one of aluminum oxide, titanium oxide, silicon oxide, silicon nitride, silicon oxynitride, zirconium oxide, or hafnium oxide. In this embodiment, the first insulating layer 10 is illustrated as a single-layer silicon oxide layer. Insulating layers to be described later may be inorganic layers and/or organic layers and have a single-layer or multi-layer structure. An inorganic layer may include at least one of the above materials, but the embodiment of the inventive concept is not limited thereto.

The first insulating layer 10 may cover a lower conductive layer BCL1. In other words, the display panel DP may further include the lower conductive layer BCL1 that overlaps the connection transistor TR1. The lower conductive layer BCL1 may prevent the electric potential caused by the polarization phenomenon of the base layer BS from affecting the connection transistor TR1. In addition, the lower conductive layer BCL1 may block light incident from the lower side to the connection transistor TR1. At least one of an inorganic barrier layer or a buffer layer may be further disposed between the lower conductive layer BCL1 and the base layer BS.

The lower conductive layer BCL1 may include a reflective metal. For example, the lower conductive layer BCL1 may include titanium (Ti), molybdenum (Mo), an alloy containing molybdenum, aluminum (Al), an alloy containing aluminum, aluminum nitride (AlN), tungsten (W), tungsten nitride (WN), copper (Cu), and the like.

In an embodiment of the inventive concept, the lower conductive layer BCL1 may be connected to the source of the connection transistor TR1 (or transistor) through a source electrode pattern S1. In this configuration, the lower conductive layer BCL1 may be synchronized with the source of the connection transistor TR1. However, this is merely an example, and the lower conductive layer BCL1 may be connected to and synchronized with the gate of the connection transistor TR1. Alternatively, the lower conductive layer BCL1 may be connected to another electrode to independently receive a constant voltage or a pulse signal. Alternatively, the lower conductive layer BCL1 may be provided such that it is isolated from other conductive patterns. The lower conductive layer BCL1 according to an embodiment of the inventive concept may be provided in various forms and is not limited to any one embodiment.

The connection transistor TR1 may be disposed on the first insulating layer 10. The connection transistor TR1 may include a semiconductor pattern SP and a gate electrode GE1. The semiconductor pattern SP may be disposed on the first insulating layer 10. The semiconductor pattern SP may include an oxide semiconductor. For example, the oxide semiconductor may include transparent conductive oxide (TCO) such as indium tin oxide (ITO), indium zinc oxide (IZO), indium gallium zinc oxide (IGZO), zinc oxide (ZnO) or indium oxide (In₂O₃). Without being limited thereto, however, the semiconductor pattern SP may include amorphous silicon, low-temperature polycrystalline silicon, or polycrystalline silicon.

The semiconductor pattern SP may include a source region SR1, a drain region DR_1, and a channel region CR1, which are divided according to the degree of conductivity. The channel region CR1 may overlap the gate electrode GE1 on a plane. The source region SR1 and the drain region DR_1 may be spaced apart from each other with the channel region CR1 interposed therebetween. When the semiconductor pattern SP is an oxide semiconductor, each of the source region SR1 and the drain region DR_1 may be a reduced region. Accordingly, the source region SR1 and the drain region DR_1 have a reduced metal content which is relatively higher than that of the channel region CR1. Alternatively, when the semiconductor pattern SP is polycrystalline silicon, each of the source region SR1 and the drain region DR_1 may be a region doped at a high concentration.

The source region SR1 and the drain region DR_1 may have relatively higher conductivity than the channel region CR1. The source region SR1 may correspond to the source electrode of the connection transistor TR1, and the drain region DR_1 may correspond to the drain electrode of the connection transistor TR1. As illustrated in FIG. 5, a separate source electrode pattern S1 and a separate drain electrode pattern D1 respectively connected to the source region SR1 and the drain region DR_1 may be further provided. Specifically, each of the separate source electrode pattern S1 and the separate drain electrode pattern D1 may be integrally formed with one of the lines constituting the pixel driver PDC (see FIG. 2A), PDC-1 (see FIG. 2B), or PDC-2 (see FIG. 2C).

The second insulating layer 20 may overlap a plurality of pixels in common and cover the semiconductor pattern SP. The second insulating layer 20 may be an inorganic layer and/or an organic layer and have a single-layer or multi-layer structure. The second insulating layer 20 may include at least one of aluminum oxide, titanium oxide, silicon oxide, silicon nitride, silicon oxynitride, zirconium oxide, or hafnium oxide. In this embodiment, the second insulating layer 20 may be a single-layer silicon oxide layer.

The gate electrode GE1 may be disposed on the second insulating layer 20. The gate electrode GE1 may correspond to the gate of the connection transistor TR1. In addition, the gate electrode GE1 may be disposed above the semiconductor pattern SP. However, this is merely an example, and the gate electrode GE1 may be disposed below the semiconductor pattern SP.

The gate electrode GE1 may include titanium (Ti), silver (Ag), molybdenum (Mo), aluminum (Al), aluminum nitride (AlN), tungsten (W), tungsten nitride (WN), copper (Cu), or alloys thereof, but the embodiment of the inventive concept is not particularly limited thereto.

The third insulating layer 30 may be disposed on the gate electrode GE1. The third insulating layer 30 may be an inorganic layer and/or an organic layer and have a single-layer or multi-layer structure.

Among a plurality of conductive patterns S1, D2, CPE1, CPE2, and CPE3, a first capacitor electrode CPE1 and a second capacitor electrode CPE2 constitute the first capacitor C1. The first capacitor electrode CPE1 and the second capacitor electrode CPE2 may be spaced apart from each other with the first insulating layer 10 and the second insulating layer 20 interposed therebetween.

In an embodiment of the inventive concept, the first capacitor electrode CPE1 and the lower conductive layer BCL1 may have an integrated shape. In addition, the second capacitor electrode CPE2 and the gate electrode GE1 may have an integrated shape.

A third capacitor electrode CPE3 may be disposed on the third insulating layer 30. The third capacitor electrode CPE3 may be spaced apart from the second capacitor electrode CPE2 with the third insulating layer 30 interposed therebetween and overlap the second capacitor electrode CPE2 on a plane. The third capacitor electrode CPE3 and the second capacitor electrode CPE2 may constitute the second capacitor C2.

The fourth insulating layer 40 may be disposed on the third insulating layer 30 and/or the third capacitor electrode CPE3. The fourth insulating layer 40 may be an inorganic layer and/or an organic layer and have a single-layer or multi-layer structure. The fourth insulating layer 40 may include at least one of aluminum oxide, titanium oxide, silicon oxide, silicon nitride, silicon oxynitride, zirconium oxide, or hafnium oxide.

The source electrode pattern S1 and the drain electrode pattern D1 may be disposed on the fourth insulating layer 40. The source electrode pattern S1 may be connected to the source region SR1 of the connection transistor TR1 through a first contact hole CNT1, and the source electrode pattern S1 and the source region SR1 of the semiconductor pattern SP may function as the source of the connection transistor TR1. The drain electrode pattern D1 may be connected to the drain region DR_1 of the connection transistor TR1 through a second contact hole CNT2, and the drain electrode pattern D1 and the drain region DR_1 of the semiconductor pattern SP may function as the drain of the connection transistor TR1.

The fifth insulating layer 50 may be disposed on the source electrode pattern S1 and the drain electrode pattern D1. In this specification, the fifth insulating layer 50 may also be referred to as a first driving insulating layer 50. The first driving insulating layer 50 may cover the pixel driver PDC.

The intermediate connection electrode CN may be disposed on the fifth insulating layer 50. The intermediate connection electrode CN may electrically connect the pixel driver PDC and the connection electrode CNE to each other. In other words, the intermediate connection electrode CN may electrically connect the connection transistor TR1 and the light-emitting element LD to each other. The intermediate connection electrode CN may be a connection node connecting the pixel driver PDC and the light-emitting element LD to each other. For example, the intermediate connection electrode CN may correspond to the fourth node N4 (see FIG. 2A) illustrated in FIG. 2A, the second node N2 (see FIG. 2B) illustrated in FIG. 2B, or the fourth node N4 (see FIG. 2C) illustrated in FIG. 2C.

The intermediate connection electrode CN may include a first layer L1, a second layer L2, and a third layer L3 which are sequentially stacked along the third direction DR3. The second layer L2 may include a material different from that of the first layer L1. In addition, the second layer L2 may include a material different from that of the third layer L3. The second layer L2 may have a thickness greater than the first layer L1. In addition, the second layer L2 may have a thickness greater than the third layer L3. The second layer L2 may include a highly conductive material. In an embodiment of the inventive concept, the second layer L2 may include aluminum (Al).

The sixth insulating layer 60 may be disposed on the intermediate connection electrode CN. In this specification, the sixth insulating layer 60 may also be referred to as a second driving insulating layer 60. The sixth insulating layer 60 may be disposed on the fifth insulating layer 50 (or the first driving insulating layer) to cover at least a portion of the intermediate connection electrode CN. Each of the fifth insulating layer 50 and the sixth insulating layer 60 may be an organic layer. For example, each of the fifth insulating layer 50 and the sixth insulating layer 60 may include a general-purpose polymer such as benzocyclobutene (BCB), polyimide, hexamethyldisiloxane (HMDSO), polymethylmethacrylate (PMMA), or polystyrene (PS), a polymer derivative having a phenol-based group, an acrylic-based polymer, an imide-based polymer, an aryl ether-based polymer, an amide-based polymer, a fluorine-based polymer, a p-xylene-based polymer, a vinyl alcohol-based polymer, and blends thereof.

A through hole OP-60 exposing at least a portion of the intermediate connection electrode CN may be provided in the sixth insulating layer 60. The intermediate connection electrode CN may be connected to the connection electrode CNE through the portion exposed from the sixth insulating layer 60 and may also be electrically connected to the light-emitting element LD. In other words, the intermediate connection electrode CN, together with the connection electrode CNE, may electrically connect the connection transistor TR1 to the light-emitting element LD. In the display panel DP according to an embodiment of the inventive concept, the sixth insulating layer 60 may be omitted or provided in plural. When the sixth insulating layer 60 is omitted, the intermediate connection electrode CN may also be omitted.

According to this inventive concept, the contact between the lower surface of the connection electrode CNE and the upper surface of the intermediate connection electrode CN enhances contact reliability. Accordingly, the size of the through holes OP-P used to connect the connection electrode CNE and the intermediate connection electrode CN can be reduced or minimized. This, in turn, facilitates an increase in the area and resolution of the light-emitting portion of the display panel DP.

The light-emitting element layer LDL may be disposed on the driving element layer DDL. The light-emitting element layer LDL may include a pixel definition layer PDL, a light-emitting element LD, and separators SPR and SPR_N.

The pixel definition layer PDL may be an organic layer. For example, the pixel definition layer PDL may include a general-purpose polymer such as benzocyclobutene (BCB), polyimide, hexamethyldisiloxane (HMDSO), polymethylmethacrylate (PMMA), or polystyrene (PS), a polymer derivative having a phenol-based group, an acrylic-based polymer, an imide-based polymer, an aryl ether-based polymer, an amide-based polymer, a fluorine-based polymer, a p-xylene-based polymer, a vinyl alcohol-based polymer, and blends thereof.

In an embodiment of the inventive concept, the pixel definition layer PDL has light-absorbing properties and, for example, may be a black color. In other words, the pixel definition layer PDL may include a black coloring agent. The black coloring agent may include a black dye and a black pigment. The black coloring agent may include carbon black, a metal such as chromium, or an oxide thereof. The pixel definition layer PDL may correspond to a light blocking pattern with the property of blocking light.

An opening OP-PDL (hereinafter referred to as a light-emitting opening) exposing at least a portion of a lower electrode EL1, which will be described later, may be defined in the pixel definition layer PDL. The light-emitting opening OP-PDL may be provided in plural and they may be disposed to respectively correspond to light-emitting elements LD. All of the components of the light-emitting element LD may overlap each other in the light-emitting opening OP-PDL. The light-emitting opening OP-PDL may be a region in which light emitted by the light-emitting element LD is displayed. Accordingly, the shape of the light-emitting portion EP1 (see FIG. 4A) may substantially correspond to the shape of the light-emitting opening OP-PDL on a plane.

The connection electrode CNE may be disposed on the pixel definition layer PDL. The connection electrode CNE may electrically connect the pixel driver PDC and the light-emitting element LD. In other words, the pixel driver PDC may be electrically connected to the light-emitting element LD via the intermediate connection electrode CN and the connection electrode CNE. The connection electrode CNE may correspond to the first connection electrode CNE1 illustrated in FIG. 4A. The second connection electrode CNE2 (see FIG. 4A) and the third connection electrode CNE3 (see FIG. 4A) may also have a structure similar to that of the first connection electrode CNE1. The second electrode EL2 of the light-emitting element LD may be connected to (or in contact with) the connection electrode CNE in regions adjacent to the outer side surfaces of the separators SPR and SPR_N. The regions adjacent to the outer side surfaces of the separators SPR and SPR_N where the second electrode EL2 contacts the connection electrode CNE may also be adjacent to top surfaces of the pixel definition layer PDL.

The connection electrode CNE may include a transparent conductive oxide (TCO) such as indium tin oxide (ITO), indium zinc oxide (IZO), indium gallium zinc oxide (IGZO), zinc oxide (ZnO), or indium oxide (In₂O₃). However, the material constituting the connection electrode CNE is not limited to the above examples.

According to an embodiment of the inventive concept, the connection electrode CNE has a shape that surrounds at least a portion of the light-emitting portion EP1 (see FIG. 4A) defined within the light-emitting element LD. As a result, the flexibility in determining the connections positions between the connection electrode CNE and the light-emitting element LD, as well as between the connection electrode CNE and the pixel driver PDC, may be improved.

In addition, since the lower surface of the connection electrode CNE and the upper surface of the intermediate connection electrode CN are in contact with each other, contact reliability may be improved. Accordingly, the sizes of the through holes OP-P and OP-60 for connecting the connection electrode CNE and the intermediate connection electrode CN to each other may be reduced or minimized. Accordingly, the area or resolution of the light-emitting portion of the display panel DP may be easily increased.

A through hole OP-P spaced apart from the light-emitting opening OP-PDL may be defined in the pixel definition layer PDL. The through hole OP-P may be provided in plural, and they may be disposed to respectively correspond to light-emitting elements LD. The size of the through hole OP-P defined in the pixel definition layer PDL may be larger than the size of the through hole OP-60 defined in the sixth insulating layer 60. The connection electrode CNE may be disposed in the through hole OP-P and the through hole OP-60 and connected to the intermediate connection electrode CN.

The light-emitting element LD may overlap the display region DA. The light-emitting element LD may include a first electrode EL1, an intermediate layer IML, and a second electrode EL2.

The first electrode EL1 may be a semi-transmissive, transmissive, or reflective electrode. According to an embodiment of the inventive concept, the first electrode EL1 may include a reflective layer formed of silver (Ag), magnesium (Mg), aluminum (Al), platinum (Pt), palladium (Pd), gold (Au), nickel (Ni), neodymium (Nd), iridium (Ir), chromium (Cr), or a compound thereof and a transparent or semi-transparent electrode layer formed on the reflective layer. The transparent or semi-transparent electrode layer may include at least one selected from the group consisting of indium tin oxide (ITO), indium zinc oxide (IZO), indium gallium zinc oxide (IGZO), zinc oxide (ZnO) or indium oxide (In₂O₃), and aluminum-doped zinc oxide (AZO). For example, the first electrode EL1 may include a stacked structure of ITO/Ag/ITO.

In this embodiment, the first electrode EL1 may be the anode of the light-emitting element LD. In other words, the first electrode EL1 may be connected to the first power line VDL (see FIG. 2A), and the first power voltage VDD (see FIG. 2A) may be applied. The first electrode EL1 may be connected to the first power line VDL within the display region DA (see FIG. 3A or FIG. 3B), or may be connected to the first power line VDL in the peripheral region NDA. In the latter case, the first power line VDL may be disposed in the peripheral region NDA (see FIG. 3A or FIG. 3B), and the first electrode EL1 may be shaped to extend into the peripheral region NDA.

In the cross-sectional view of FIG. 5, the first electrode EL1 is illustrated as overlapping the light-emitting opening OP-PDL and not overlapping the separators SPR and SPR_N. However, as described above in FIG. 4D, the first electrodes EL1 of the light-emitting elements LD may have an integrated shape and can feature a mesh or lattice design with openings defined in certain regions. In other words, as long as a same first power voltage VDD can be applied to the first electrode EL1 of each light-emitting element LD, the shape of the first electrode EL1 may vary.

The intermediate layer IML may be disposed between the first electrode EL1 and the second electrode EL2. The intermediate layer IML may include a light-emitting layer EML and a functional layer FNL having a larger area than the light-emitting layer EML. The light-emitting element LD may include an intermediate layer IML with various structures and the inventive concept is not limited to any one embodiment. For example, the functional layer FNL may consist of a plurality of layers or two or more layers spaced apart from each other with the light-emitting layer EML interposed therebetween.

The light-emitting layer EML may include an organic light-emitting material. In addition, the light-emitting layer EML may include an inorganic light-emitting material, or a mixed layer of an organic light-emitting material and an inorganic light-emitting material. In this embodiment, the light-emitting layers EML included in adjacent light-emitting portions EP (see FIG. 3A) may include light-emitting materials that display different colors. For example, the light-emitting layers EML included in light-emitting portions EP may provide any one of blue light, red light, and green light. Without being limited thereto, however, the light-emitting layers EML disposed in all of the light-emitting portions EP may include a light-emitting material that displays the same color. In this case, the light-emitting layer EML may provide blue light or white light.

The functional layer FNL may be disposed between the first electrode EL1 and the second electrode EL2. Specifically, the functional layer FNL may include a first intermediate functional layer disposed between the first electrode EL1 and the light-emitting layer EML and a second intermediate functional layer disposed between the second electrode EL2 and the light-emitting layer EML. In an embodiment of the inventive concept, one of the first intermediate functional layer and the second intermediate functional layer may be omitted. In this embodiment, the light-emitting layer EML is illustrated as being inserted into the functional layer FNL. In other words, the light-emitting layer EML is disposed between the first intermediate functional layer and the second intermediate functional layer of the functional layer FNL.

The functional layer FNL may control the movement of charge between the first electrode EL1 and the second electrode EL2. For example, the first intermediate functional layer may include a hole injection/transport material and/or an electron injection/transport material. The second intermediate functional layer may include at least one of an electron blocking layer, a hole transport layer, a hole injection layer, a hole blocking layer, an electron transport layer, an electron injection layer, and a charge generation layer.

The second electrode EL2 may be disposed on the intermediate layer IML. As described above, the second electrode EL2 may be electrically connected to the pixel driver PDC by being connected to the connection electrode CNE. In other words, the second electrode EL2 may be electrically connected to the connection transistor TR1 through the connection electrode CNE.

The separators SPR and SPR_N may be disposed on the pixel definition layer PDL. The separators SPR and SPR_N may protrude in the thickness direction (e.g., the third direction DR3) of the driving element layer DDL. In other words, the separators SPR and SPR_N may protrude from the upper surface of the pixel definition layer PDL toward the sensing layer ISL. The separators SPR and SPR_N may include first separators SPR disposed in the display region DA or the peripheral region NDA and second separators SPR_N disposed in the peripheral region NDA. The first separators SPR may have a symmetrical shape, and the second separators SPR_N may have an asymmetrical shape.

The display panel DP may further include a dummy layer UP disposed on the first separators SPR and an outer dummy layer UP_N disposed on the second separators SPR_N. The dummy layer UP may include a first dummy layer UP1 disposed on the first separators SPR and a second dummy layer UP2 disposed on the first dummy layer UP1. For example, the first dummy layer UP1 may make direct contact with the first separators SPR. The outer dummy layer UP_N may include a first outer dummy layer UP1_N disposed on the second separators SPR_N and a second outer dummy layer UP2_N disposed on the first outer dummy layer UP1_N. For example, the first outer dummy layer UP1_N may make direct contact with the second separators SPR_N.

The first dummy layer UP1 and the first outer dummy layer UP1_N may include the same material as the intermediate layer IML and they may be formed by the same process. The second dummy layer UP2 and the second outer dummy layer UP2_N may include the same material as the second electrode EL2 and they may be formed by the same process. In other words, the first dummy layer UP1 and the first outer dummy layer UP1_N may be formed simultaneously during a process of forming the intermediate layer IML, and the second dummy layer UP2 and the second outer dummy layer UP2_N may be formed simultaneously during a process of forming the second electrode EL2. As illustrated in FIG. 5, the dummy layer UP and the outer dummy layer UP_N may be formed not only on the upper surfaces of the separators SPR and SPR_N but also on portions of the side surfaces thereof. In other words, the dummy layer UP and the outer dummy layer UP_N may almost completely surround the separators SPR and SPR_N, respectively.

The encapsulation layer ECL may include a first inorganic layer IL1, an organic layer OL, and a second inorganic layer IL2. The first and second inorganic layers IL1 and IL2 may protect the light-emitting element LD from moisture and oxygen outside the display panel DP, and the organic layer OL may protect the light-emitting element LD from foreign substances, such as particles left during the formation process of the first inorganic layer IL1. The first and second inorganic layers IL1 and IL2 may include a silicon nitride layer, a silicon oxynitride layer, a silicon oxide layer, a titanium oxide layer, or an aluminum oxide layer. The organic layer OL may include an acrylic-based organic layer, and the type of material is not limited to any one embodiment. However, this is an example, and the encapsulation layer ECL may additionally include a plurality of inorganic layers and organic layers.

The sensing layer ISL may sense an external input. In this embodiment, the sensing layer ISL may be formed on the encapsulation layer ECL through a continuous process. In this case, the sensing layer ISL may be disposed directly on the encapsulation layer ECL. Being directly disposed may mean that no other components are disposed between the sensing layer ISL and the encapsulation layer ECL. In other words, a separate adhesive member may not be disposed between the sensing layer ISL and the encapsulation layer ECL. However, this is merely an example, and in the display panel DP according to an embodiment of the inventive concept, the sensing layer ISL may be separately formed and then coupled to the display panel DP by an adhesive member.

The sensing layer ISL may include a plurality of conductive layers and a plurality of insulating layers. The plurality of conductive layers may include a first sensing conductive layer MTL1 and a second sensing conductive layer MTL2, and the plurality of insulating layers may include first to third sensing insulating layers 71, 72, and 73. However, this is merely an example, and the number of the conductive layers and the number of the insulating layers are not limited thereto.

Each of the first to third sensing insulating layers 71, 72, and 73 may have a single-layer structure or a multi-layer structure in which layers are stacked along the third direction DR3. The first to third sensing insulating layers 71, 72, and 73 may include an inorganic film. The inorganic film may include at least one of aluminum oxide, titanium oxide, silicon oxide, silicon nitride, silicon oxynitride, zirconium oxide, or hafnium oxide. The first to third sensing insulating layers 71, 72, and 73 may include an organic film. The organic film may include at least any one of an acrylic-based resin, a methacrylic-based resin, polyisoprene, a vinyl-based resin, an epoxy-based resin, a urethane-based resin, a cellulose-based resin, a siloxane-based resin, a polyimide-based resin, a polyamide-based resin, or a perylene-based resin.

The first sensing conductive layer MTL1 may be disposed between the first sensing insulating layer 71 and the second sensing insulating layer 72, and the second sensing conductive layer MTL2 may be disposed between the second sensing insulating layer 72 and the third sensing insulating layer 73. A portion of the second sensing conductive layer MTL2 may be connected to the first sensing conductive layer MTL1 through a contact hole CNT formed in the second sensing insulating layer 72. Each of the first sensing conductive layer MTL1 and the second sensing conductive layer MTL2 may have a single-layer structure or a multi-layer structure in which layers are stacked along the third direction DR3.

A single-layer sensing conductive layer may include a metal layer or a transparent conductive layer. The metal layer may include molybdenum, silver, titanium, copper, aluminum, or alloys thereof. The transparent conductive layer may include a transparent conductive oxide such as indium tin oxide (ITO), indium zinc oxide (IZO), zinc oxide (ZnO), or indium zinc tin oxide (IZTO). Alternatively, the transparent conductive layer may include a conductive polymer such as PEDOT, metal nanowire, graphene, and the like.

A multi-layer sensing conductive layer may include metal layers. The metal layers may have, for example, a three-layer structure of titanium (Ti)/aluminum (Al)/titanium (Ti). Alternatively, the multi-layer sensing conductive layer may include at least one metal layer and at least one transparent conductive layer.

The first sensing conductive layer MTL1 and the second sensing conductive layer MTL2 may form a sensor that senses an external input in the sensing layer ISL. The sensor may be driven by a capacitive method and, in particular, may be driven by either a mutual-capacitance method or a self-capacitance method. However, this is merely an example, and the sensor may be driven by a resistive method, an ultrasonic method, or an infrared method in addition to the capacitive method, and the inventive concept is not limited to any of these methods.

Each of the first sensing conductive layer MTL1 and the second sensing conductive layer MTL2 may include a transparent conductive oxide and have a metal mesh shape formed of an opaque conductive material. As long as the visibility of an image displayed by the display panel DP is not reduced, the first sensing conductive layer MTL1 and the second sensing conductive layer MTL2 may include various materials and have various shapes.

FIG. 6 is an enlarged view of a region corresponding to region AA′ of FIG. 5.

Referring to FIGS. 5 and 6, the second separator SPR_N may have an asymmetrical shape. For example, an interior angle Q1 formed by a lower surface B_SPR of the second separator SPR_N and a first side surface SL1 of the second separator SPR_N in the first region AR1 may be larger than an interior angle Q2 formed by the lower surface B_SPR of the second separator SPR_N and a second side surface SL2 of the second separator SPR_N in the second region AR2. In other words, the angle between the first side surface SL1 of the second separator SPR_N, adjacent to the display region DA, and the normal direction of the peripheral region NDA (or the normal direction of the display region DA) may be greater than the angle between the second side surface SL2 of the second separator SPR_N, adjacent to the peripheral region NDA, and the normal direction of the peripheral region NDA (or the normal direction of the display region DA). The first side surface SL1 of the second separator SPR_N adjacent to the display region DA may have a more deeply etched shape. In other words, the first side surface SL1 of the second separator SPR_N, adjacent to the display region DA, may exhibit a more deeply etched profile.

An outer dummy layer UP_N may be disposed on the second separator SPR_N. The outer dummy layer UP_N may be formed such that is separated from the intermediate layer IML and the second electrode EL2 adjacent to the first region AR1 by the second separator SPR_N. In other words, the outer dummy layer UP_N may be simultaneously formed in a process of forming the intermediate layer IML and the second electrode EL2.

The asymmetrical shape of the second separator SPR_N may result from the connection electrode CNE positioned beneath a portion of the lower section of the second separator SPR_N. For example, the second separator SPR_N may include a first region AR1 and a second region AR2. In the first region AR1, the second separator SPR_N may overlap the connection electrode CNE in a planar view, whereas in the second region AR2, the second separator SPR_N may not overlap the connection electrode CNE in a planar view.

A portion of the second separator SPR_N located in the region where the connection electrode CNE is formed may exhibit a more deeply etched shape. This deeply etched second separator SPR_N may disconnect the intermediate layer IML and the second electrode EL2 adjacent to the first region AR1. In other words, the intermediate layer IML and the second electrode EL2 adjacent to the first region AR1 may be separated from the outer dummy layer UP_N by the first inorganic layer IL1 at the first side surface SL1 of the second separator SPR_N.

A portion of the second separator SPR_N disposed on a region where the connection electrode CNE is not formed may have a relatively less etched shape. As a result, the intermediate layer IML and the second electrode EL2 adjacent to the second region AR2 may not be disconnected by the second side surface SL2 of the second separator SPR_N. In other words, the intermediate layer IML and the second electrode EL2 adjacent to the second region AR2 may remain connected, as they are not separated at the second side surface SL2 of the second separator SPR_N. Therefore, the outer dummy layer UP_N (or the intermediate layer IML and the second electrode EL2) disposed on the second separator SPR_N may extend toward the peripheral region NDA. The extended outer dummy layer UP_N may be electrically connected to the first electrode EL1 in the peripheral region NDA.

FIG. 7 is an enlarged view of a region corresponding to region AA′ of FIG. 5. In describing FIG. 7, reference will be made to FIGS. 5 and 6. To avoid redundancy, descriptions of elements denoted by the same reference numerals will be omitted.

Referring to FIGS. 5 and 7, a second separator SPR_Na may have an asymmetrical shape. An outer dummy layer UP_Na may be disposed on the second separator SPR_Na.

The asymmetrical shape of the second separator SPR_Na may be formed by a pixel definition layer PDLa and a connection electrode CNE disposed below a portion of the lower portion of the second separator SPR_Na. The second separator SPR_Na may include a first region AR1 and a second region AR2. In the first region AR1, the second separator SPR_Na may overlap the connection electrode CNE on a plane, and in the second region AR2, the second separator SPR_Na may not overlap the connection electrode CNE on a plane. The thickness of the pixel definition layer PDLa adjacent to or overlapping the second region AR2 may be smaller than its thickness adjacent to the first region AR1.

A portion of the second separator SPR_Na located in the region where the connection electrode CNE is formed and positioned on a relatively thick portion of the pixel definition layer PDLa may exhibit a more deeply etched shape. This deeply etched second separator SPR_Na may disconnect the intermediate layer IML and the second electrode EL2 adjacent to the first region AR1.

A portion of the second separator SPR_Na located in the region where the connection electrode CNE is not formed and positioned on a relatively thin portion of the pixel definition layer PDLa may exhibit a relatively less etched shape. In addition, the angle formed between the second separator SPR_Na and the pixel definition layer PDLa may be more gradual. Therefore, the intermediate layer IML and the second electrode EL2 adjacent to the second region AR2 may not be disconnected by the second separator SPR_Na. Therefore, the outer dummy layer UP_Na (or the intermediate layer IML and the second electrode EL2) disposed on the second separator SPR_Na may extend toward the peripheral region NDA, with the extended outer dummy layer UP_Na establishing an electrical connection with the first electrode EL1 in the peripheral region NDA.

FIG. 8 is an enlarged view of a region corresponding to region AA′ of FIG. 5. In describing FIG. 8, reference will be made to FIG. 5 and FIG. 6. To avoid redundancy, descriptions of elements denoted by the same reference numerals will be omitted.

Referring to FIG. 5 and FIG. 8, a second separator SPR_Nb may have an asymmetrical shape. An outer dummy layer UP_Nb may be disposed on the second separator SPR_Nb.

The asymmetrical shape of the second separator SPR_Nb may be formed by a second driving insulating layer 60a and a connection electrode CNE disposed below a section of the lower portion of the second separator SPR_Nb. The second separator SPR_Nb may include a first region AR1 and a second region AR2. The first region AR1 of the second separator SPR_Nb may overlap the connection electrode CNE on a plane, and the second region AR2 of the second separator SPR_Nb may not overlap the connection electrode CNE on a plane. The thickness of the second driving insulating layer 60a adjacent to or overlapping the second region AR2 may be less than the thickness of the second driving insulating layer 60a adjacent to the first region AR1.

A portion of the second separator SPR_Nb disposed on a region, where the connection electrode CNE is formed, and disposed on a relatively thick portion of the second driving insulating layer 60a may have a more deeply etched shape. As a result, the intermediate layer IML and the second electrode EL2 adjacent to the first region AR1 may be disconnected by the deeply etched second separator SPR_Nb.

A portion of the second separator SPR_Nb disposed on a region, where the connection electrode CNE is not formed, and disposed on a relatively thin portion of the second driving insulating layer 60a may have a relatively less etched shape. In addition, an angle formed by the second separator SPR_Nb and the pixel definition layer PDL disposed on the second driving insulating layer 60a may be gradual. Therefore, the intermediate layer IML and the second electrode EL2 adjacent to the second region AR2 may not be disconnected by the second separator SPR_Nb. Accordingly, the outer dummy layer UP_Nb (or the intermediate layer IML and the second electrode EL2) disposed on the second separator SPR_Nb may extend toward the peripheral region NDA, and the extended outer dummy layer UP_Nb may be electrically connected to the first electrode EL1 in the peripheral region NDA.

In FIG. 8, the second driving insulating layer 60a having a different thickness is illustrated as an example, but the embodiment of the inventive concept is not limited thereto. For example, the asymmetrical shape of the second separator SPR_Nb may be formed by the first driving insulating layer 50 and the connection electrode CNE disposed below a section of the lower portion of the second separator SPR_Nb. Additionally, the thickness of the first driving insulating layer 50 adjacent to the second region AR2 may be smaller than the thickness of the first driving insulating layer 50 adjacent to the first region AR1. In another embodiment of the inventive concept, the asymmetrical shape of the second separator SPR_Nb overlapping the peripheral region NDA may be formed by the first and second driving insulating layers 50 and 60a and the connection electrode CNE disposed below the second separator SPR_Nb. Additionally, the thicknesses of the first and second driving insulating layers 50 and 60a adjacent to the second region AR2 may be smaller than the thicknesses of the first and second driving insulating layers 50 and 60a adjacent to the first region AR1.

FIG. 9 is an enlarged view of a region corresponding to region AA′ of FIG. 5. In describing FIG. 9, reference will be made to FIGS. 5 and 6. To avoid redundancy, descriptions of elements denoted by the same reference numerals will be omitted.

Referring to FIG. 5 and FIG. 9, the display panel DP (see FIG. 5) may further include: a first protrusion pattern SP1 disposed on a pixel definition layer PDL and a second separator SPR_Nc; and an outer dummy layer UP_Nc disposed on the second separator SPR_Nc and the first protrusion pattern SP1. The first protrusion pattern SP1 may be disposed to be adjacent to or overlapping the second region AR2. The first protrusion pattern SP1 may be disposed on a side surface and an upper surface of the second separator SPR_Nc. The outer dummy layer UP_Nc may be formed by being separated from the intermediate layer IML and the second electrode EL2 adjacent to the first region AR1 by the second separator SPR_Nc. In other words, the outer dummy layer UP_Nc may be formed simultaneously in a process of forming the intermediate layer IML and the second electrode EL2.

The second separator SPR_Nc may have an asymmetrical shape. The asymmetrical shape of the second separator SPR_Nc may be formed by a connection electrode CNE disposed below a section of the lower portion of the second separator SPR_Nc. For example, the second separator SPR_Nc may include a first region AR1 and a second region AR2. The first region AR1 of the second separator SPR_Nc may overlap the connection electrode CNE on a plane, and the second region AR2 of the second separator SPR_Nc may not overlap the connection electrode CNE on a plane.

A portion of the second separator SPR_Nc disposed on a region where the connection electrode CNE is formed may have a more deeply etched shape, and the intermediate layer IML and the second electrode EL2 adjacent to the first region AR1 may be disconnected by the deeply etched second separator SPR_Nc.

A portion of the second separator SPR_Nc disposed on a region where the connection electrode CNE is not formed may have a relatively less etched shape. The intermediate layer IML and the second electrode EL2 adjacent to the second region AR2 may not be disconnected by the second separator SPR_Nc due to the relatively less etched shape of the second separator SPR_Nc and the first protrusion pattern SP1, which protrudes in the thickness direction (for example, the third direction DR3) of the second separator SPR_Nc. Accordingly, the outer dummy layer UP_Nc (or the intermediate layer IML and the second electrode EL2) disposed on the second separator SPR_Nc may extend toward the peripheral region NDA, and the extended outer dummy layer UP_Nc may be electrically connected to the first electrode EL1 in the peripheral region NDA.

FIG. 10 is an enlarged view of a region corresponding to region AA′ of FIG. 5. In describing FIG. 10, reference will be made to FIG. 5 and FIG. 6. To avoid redundancy, descriptions of elements denoted by the same reference numerals will be omitted.

Referring to FIG. 5 and FIG. 10, the display panel DP (see FIG. 5) may further include a second protrusion pattern SP2 disposed between a pixel definition layer PDL and a second separator SPR_Nd. The width of the second protrusion pattern SP2 in one direction (for example, in the first direction DR1 or the second direction DR2) may be larger than the width of the second separator SPR_Nd in the one direction. An outer dummy layer UP_Nd may be disposed on the second separator SPR_Nd.

The asymmetrical shape of the second separator SPR_Nd may be formed by a connection electrode CNE disposed below a section of the lower portion of the second separator SPR_Nd. For example, the second separator SPR_Nd may include a first region AR1 and a second region AR2. The first region AR1 of the second separator SPR_Nd may overlap the connection electrode CNE on a plane, and the second region AR2 of the second separator SPR_Nd may not overlap the connection electrode CNE on a plane.

A portion of the second separator SPR_Nd disposed on a region where the connection electrode CNE is formed may have a more deeply etched shape, and the intermediate layer IML and the second electrode EL2 adjacent to the first region AR1 may be disconnected by the deeply etched second separator SPR_Nd.

A portion of the second separator SPR_Nd disposed on a region where the connection electrode CNE is not formed may have a relatively less etched shape. The intermediate layer IML and the second electrode EL2 adjacent to the second region AR2 may not be disconnected by the second separator SPR_Nd due to the relatively less etched shape of the second separator SPR_Nd and the second protrusion pattern SP2 protruding in the thickness direction (for example, the third direction DR3) of the pixel definition layer PDL on the pixel definition layer PDL. Accordingly, the outer dummy layer UP_Nd (or the intermediate layer IML and the second electrode EL2) disposed on the second separator SPR_Nd may extend toward the peripheral region NDA, and the extended outer dummy layer UP_Nd may be electrically connected to the first electrode EL1 in the peripheral region NDA.

FIG. 11 is an enlarged view of a region corresponding to region AA′ of FIG. 5. In describing FIG. 11, reference will be made to FIG. 5 and FIG. 6. To avoid redundancy, descriptions of elements denoted by the same reference numerals will be omitted.

Referring to FIG. 5 and FIG. 11, the display panel DP (see FIG. 5) may further include a second protrusion pattern SP2a disposed between a pixel definition layer PDL and a second separator SPR_Ne. The width of the second protrusion pattern SP2a in one direction (for example, in the first direction DR1 or the second direction DR2) may be smaller than that of the second separator SPR_Ne in the one direction. An outer dummy layer UP_Ne may be disposed on the second separator SPR_Ne.

The asymmetrical shape of the second separator SPR_Ne may be formed by a connection electrode CNE and the second protrusion pattern SP2a disposed below a section of the lower portion of the second separator SPR_Ne. For example, the second separator SPR_Ne may include a first region AR1 and a second region AR2. The first region AR1 of the second separator SPR_Ne may overlap the connection electrode CNE on a plane, and the second region AR2 of the second separator SPR_Ne may not overlap the connection electrode CNE on a plane. The second protrusion pattern SP2a may overlap the second region AR2.

A portion of the second separator SPR_Ne disposed on a region where the connection electrode CNE is formed may have a more deeply etched shape, and the intermediate layer IML and the second electrode EL2 adjacent to the first region AR1 may be disconnected by the deeply etched second separator SPR_Ne.

A portion of the second separator SPR_Ne disposed on a region where the second protrusion pattern SP2a is formed may have a shape that protrudes in the third direction DR3 along the shape of the second protrusion pattern SP2a. Due to the protruding shape of the second separator SPR_Ne, the intermediate layer IML and the second electrode EL2 adjacent to the second region AR2 may not be disconnected by the second separator SPR_Ne. Accordingly, the outer dummy layer UP_Ne (or the intermediate layer IML and the second electrode EL2) disposed on the second separator SPR_Ne may extend toward the peripheral region NDA, and the extended outer dummy layer UP_Ne may be electrically connected to the first electrode EL1 in the peripheral region NDA.

Referring to FIGS. 5 to 11, the outer dummy layers UP_N, UP_Na, UP_Nb, UP_Nc, UP_Nd, and UP_Ne (or, the intermediate layer IML and the second electrode EL2) disposed on the second separators SPR_N, SPR_Na, SPR_Nb, SPR_Nc, SPR_Nd, and SPR_Ne according to this inventive concept may extend toward the peripheral region NDA. The extended outer dummy layers UP_N, UP_Na, UP_Nb, UP_Nc, UP_Nd, and UP_Ne may be electrically connected to the first electrode EL1 in the peripheral region NDA. Since the outer dummy layers UP_N, UP_Na, UP_Nb, UP_Nc, UP_Nd, and UP_Ne and the dummy layer UP electrically connected to the outer dummy layers UP_N, UP_Na, UP_Nb, UP_Nc, UP_Nd, and UP_Ne are floating, phenomena that cause changes in current flow may be reduced or eliminated. In addition, the impact of electric field fluctuations occurring in the dummy layer UP and the outer dummy layers UP_N, UP_Na, UP_Nb, UP_Nc, UP_Nd, and UP_Ne formed on the first separators SPR and the second separators SPR_N, SPR_Na, SPR_Nb, SPR_Nc, SPR_Nd, and SPR_Ne may be reduced. This reduction in electric field fluctuations may also decrease or eliminate touch noise caused by these fluctuations.

FIG. 12A is a schematic plan view illustrating a display region DA and a peripheral region NDA according to an embodiment of the inventive concept.

Referring to FIGS. 5, 6, and 12A, a display region DA and a peripheral region NDA adjacent to the display region DA may be defined in the display panel DP. The peripheral region NDA may include a first edge region CA1, a second edge region CA2, a third edge region CA3, and a fourth edge region CA4 surrounding the display region DA. The first edge region CA1 and the third edge region CA3 may extend in the first direction DR1, and the second edge region CA2 and the fourth edge region CA4 may extend in the second direction DR2 crossing the first direction DR1. The second edge region CA2 and the fourth edge region CA4 may be connected to the first edge region CA1 and the third edge region CA3. In other words, the first to fourth edge regions CA1, CA2, CA3, and CA4 may have a tetragonal shape with a hollow or empty center. However, this is an example, and the shapes of the first to fourth edge regions CA1, CA2, CA3, and CA4 may have a circular, polygonal, or atypical shape depending on the planar shape of the display panel DP.

In an embodiment of the inventive concept, only the second separators SPR_N may be disposed in the peripheral region NDA. For example, the second separators SPR_N may be disposed in the first to fourth edge regions CA1, CA2, CA3, and CA4. The intermediate layer IML and the second electrode EL2 adjacent to the second region AR2 may not be disconnected by the second side surface SL2 of the second separator SPR_N. The outer dummy layer UP_N (or the intermediate layer IML and the second electrode EL2) disposed on the second separator SPR_N may extend toward the peripheral region NDA, and the extended outer dummy layer UP_N may be electrically connected to the first electrode EL1 in the peripheral region NDA. In other words, the outer dummy layer UP_N (or the intermediate layer IML and the second electrode EL2) may be electrically connected to the first electrode EL1 in the first to fourth edge regions CA1, CA2, CA3, and CA4.

FIG. 12B is a schematic plan view illustrating a display region DA and a peripheral region NDAa according to an embodiment of the inventive concept. In describing FIG. 12B, reference will be made to FIG. 12A, and the descriptions of the same reference numerals will be omitted.

Referring to FIGS. 5, 6, and 12B, a display region DA and a peripheral region NDAa adjacent to the display region DA may be defined in the display panel DP. The peripheral region NDAa may include a first edge region CA1a, a second edge region CA2a, a third edge region CA3a, and a fourth edge region CA4a which surround the display region DA. The first edge region CAla and the third edge region CA3a may extend in the first direction DR1, and the second edge region CA2a and the fourth edge region CA4a may extend in the second direction DR2 crossing the first direction DR1. The second edge region CA2a and the fourth edge region CA4a may be connected to the first edge region CAla and the third edge region CA3a. In other words, the first to fourth edge regions CA1a, CA2a, CA3a, and CA4a may have a tetragonal shape with an empty center. However, this is an example, and the shapes of the first to fourth edge regions CAla, CA2a, CA3a, and CA4a may have a circular, polygonal, or atypical shape depending on the planar shape of the display panel DP.

In an embodiment of the inventive concept, the second separators SPR_N may be disposed in at least one of the first to fourth edge regions CA1a, CA2a, CA3a, and CA4a, and the first separators SPR may be disposed in at least one of the remaining regions. For example, the first separators SPR may be disposed in the first to third edge regions CA1a, CA2a, and CA3a, and the second separators SPR_N may be disposed in the fourth edge region CA4a. In other words, in the fourth edge region CA4a, the outer dummy layer UP_N (or the intermediate layer IML and the second electrode EL2) may be electrically connected to the first electrode EL1.

FIG. 12C is a schematic plan view illustrating a display region DA and a peripheral region NDAb according to an embodiment of the inventive concept. In describing FIG. 12C, reference will be made to FIG. 12A, and the descriptions of the same reference numerals will be omitted.

Referring to FIG. 5, FIG. 6, and FIG. 12C, a display region DA and a peripheral region NDAb adjacent to the display region DA may be defined in the display panel DP. The peripheral region NDAb may include a first edge region CA1b, a second edge region CA2b, a third edge region CA3b, and a fourth edge region CA4b which surround the display region DA. The first edge region CA1b and the third edge region CA3b may extend in the first direction DR1, and the second edge region CA2b and the fourth edge region CA4b may extend in the second direction DR2 crossing the first direction DR1. The second edge region CA2b and the fourth edge region CA4b may be connected to the first edge region CA1b and the third edge region CA3b. In other words, the first to fourth edge regions CA1b, CA2b, CA3b, and CA4b may have a tetragonal shape with an empty center. However, this is an example, and the shapes of the first to fourth edge regions CA1b, CA2b, CA3b, and CA4b may have a circular, polygonal, or atypical shape depending on the planar shape of the display panel DP.

In an embodiment of the inventive concept, the first separators SPR may be disposed in at least one of the first to fourth edge regions CA1b, CA2b, CA3b, and CA4b, and the first separators SPR and the second separators SPR_N may be disposed in at least one of the remaining regions. In the remaining regions, the first separators SPR and the second separators SPR_N may be alternately arranged. For example, the first separators SPR may be disposed in the second edge region CA2b and the fourth edge region CA4b, and the first separators SPR and the second separators SPR_N may be disposed in the first edge region CA1b and the third edge region CA3b. In each of the first edge region CA1b and the third edge region CA3b, the first separators SPR and the second separators SPR_N may be alternately arranged. In other words, in certain portions of the first edge region CA1b and the third edge region CA3b, the outer dummy layer UP_N (or the intermediate layer IML and the second electrode EL2) may be electrically connected to the first electrode EL1.

FIG. 12D is a schematic plan view illustrating a display region DA and a peripheral region NDAc according to an embodiment of the inventive concept. In describing FIG. 12D, reference will be made to FIG. 12A, and the descriptions of the same reference numerals will be omitted.

Referring to FIGS. 5, 6, and 12D, a display region DA and a peripheral region NDAc adjacent to the display region DA may be defined in the display panel DP. The peripheral region NDAc may include a first edge region CA1c, a second edge region CA2c, a third edge region CA3c, and a fourth edge region CA4c which surround the display region DA. The first edge region CA1c and the third edge region CA3c may extend in the first direction DR1, and the second edge region CA2c and the fourth edge region CA4c may extend in the second direction DR2 crossing the first direction DR1. The second edge region CA2c and the fourth edge region CA4c may be connected to the first edge region CA1c and the third edge region CA3c. In other words, the first to fourth edge regions CA1c, CA2c, CA3c, and CA4c may have a tetragonal shape with an empty center. However, this is an example, and the shapes of the first to fourth edge regions CA1c, CA2c, CA3c, and CA4c may have a circular, polygonal, or atypical shape depending on the planar shape of the display panel DP.

In an embodiment of the inventive concept, the first separators SPR may be disposed in some of the first to fourth edge regions CA1c, CA2c, CA3c, and CA4c, while the second separators SPR_N may be disposed in others of the first to fourth edge regions CA1c, CA2c, CA3c, and CA4c. Additionally, the first separators SPR and the second separators SPR_N may be disposed in the remaining regions, where the first separators SPR and the second separators SPR_N may be alternately arranged. For example, the first separators SPR may be disposed in the second edge region CA2c, and the second separators SPR_N may be disposed in the fourth edge region CA4c. In addition, the first separators SPR and the second separators SPR_N may be disposed in the first edge region CA1c and the third edge region CA3c. The first separators SPR and the second separators SPR_N may be alternately arranged in the first edge region CA1c and the third edge region CA3c. In other words, the outer dummy layer UP_N (or the intermediate layer IML and the second electrode EL2) may be electrically connected to the first electrode EL1 in the entire fourth edge region CA4c and partial regions of the first edge region CA1c and the third edge region CA3c.

In FIGS. 12A to 12D, the second separators SPR_N illustrated in FIG. 6 are illustrated as an example, but the embodiment of the inventive concept is not limited thereto. The second separators SPR_Na, SPR_Nb, SPR_Nc, SPR_Nd, and SPR_Ne illustrated in FIGS. 7 to 11 may be disposed in the first to fourth edge regions.

As described above, the outer dummy layer (or, the intermediate layer and the second electrode) disposed on the second separators, according to an embodiment of the inventive concept, may extend toward the peripheral region. The extended outer dummy layer may establish an electrical connection with the first electrode in the peripheral region. As a result, since the outer dummy layer and the dummy layer electrically connected to the outer dummy layer are floating, phenomena that cause changes in current flow may be reduced or eliminated. In addition, the impact of electric field fluctuations occurring in the dummy layer and the outer dummy layer formed on the first separators and the second separators may be mitigated, thereby decreasing or eliminating touch noise caused by these fluctuations.

While the foregoing has been described with reference to embodiments of the inventive concept, those skilled in the art will recognize that various modifications and alterations can be made without departing from the spirit and technical scope of the inventive concept as set forth in the claims. Accordingly, the technical scope of the inventive concept should be determined by the claims provided hereinafter, rather than being limited to the detailed description within this specification.

What is claimed is:

1. An electronic device comprising a display panel having a display region and a peripheral region adjacent to the display region,
the display panel comprises:
a driving element layer comprising a pixel driver;
a plurality of light-emitting elements overlapping the display region, wherein each of the plurality of light-emitting elements comprises a first electrode, an intermediate layer disposed on the first electrode, and a second electrode disposed on the intermediate layer;
a pixel definition layer disposed on the driving element layer and having a light-emitting opening exposing a portion of the first electrode;
a connection electrode disposed on the pixel definition layer and electrically connecting the pixel driver and the second electrode to each other; and
a plurality of separators disposed on the pixel definition layer and protruding in a thickness direction of the driving element layer,
wherein the plurality of separators comprise:
a plurality of first separators disposed in the display region or the peripheral region; and
a plurality of second separators disposed in the peripheral region,
wherein the plurality of second separators comprise:
a first region overlapping the connection electrode in a planar view; and
a second region that does not overlap the connection electrode in a planar view.

2. The electronic device of claim 1, wherein the display panel further comprises:
a dummy layer disposed on the plurality of first separators; and
an outer dummy layer disposed on the plurality of second separators,
wherein the outer dummy layer extends toward the peripheral region and is electrically connected to the first electrode in the peripheral region.

3. The electronic device of claim 1, wherein:
the intermediate layer and the second electrode overlapping the display region are disconnected by the plurality of first separators; and
the intermediate layer and the second electrode adjacent to the first region of the plurality of second separators are disconnected by the plurality of second separators.

4. The electronic device of claim 1, wherein a first angle formed between a lower surface of the plurality of second separators and a first side surface of the plurality of second separators in the first region is larger than a second angle formed between the lower surface of the plurality of second separators and a second side surface of the plurality of second separators in the second region.

5. The electronic device of claim 1, wherein a thickness of the pixel definition layer adjacent to the second region is smaller than a thickness of the pixel definition layer adjacent to the first region.

6. The electronic device of claim 1, wherein the driving element layer comprises:
a first driving insulating layer covering the pixel driver; and
a second driving insulating layer disposed on the first driving insulating layer.

7. The electronic device of claim 6, wherein a thickness of the first driving insulating layer adjacent to the second region is smaller than a thickness of the first driving insulating layer adjacent to the first region.

8. The electronic device of claim 6, wherein a thickness of the second driving insulating layer adjacent to the second region is smaller than a thickness of the second driving insulating layer adjacent to the first region.

9. The electronic device of claim 1, wherein the display panel further comprises a first protrusion pattern disposed on the pixel definition layer and the plurality of second separators,
wherein the first protrusion pattern is adjacent to the second region.

10. The electronic device of claim 9, wherein the display panel further comprises an outer dummy layer disposed on the plurality of second separators and the first protrusion pattern,
wherein the outer dummy layer extends toward the peripheral region and is electrically connected to the first electrode in the peripheral region.

11. The electronic device of claim 1, wherein the display panel further comprises a second protrusion pattern disposed between the plurality of second separators and the pixel definition layer.

12. The electronic device of claim 11, wherein a width of the second protrusion pattern in one direction is larger than a width of the plurality of second separators in the one direction.

13. The electronic device of claim 11, wherein:
a width of the second protrusion pattern in one direction is smaller than a width of the plurality of second separators in the one direction; and
the second protrusion pattern is spaced apart from the connection electrode in a planar view.

14. The electronic device of claim 1, wherein the peripheral region comprises a first edge region, a second edge region, a third edge region, and a fourth edge region which surround the display region,
wherein:
the first edge region and the third edge region extend in a first direction; and
the second edge region and the fourth edge region extend in a second direction crossing the first direction.

15. The electronic device of claim 14, wherein the plurality of second separators are disposed in the first to fourth edge regions.

16. The electronic device of claim 14, wherein:
the plurality of second separators are disposed in at least one of the first to fourth edge regions; and
the plurality of first separators are disposed in at least one of the first to fourth edge regions where the plurality of second separators are not disposed.

17. The electronic device of claim 14, wherein:
the plurality of first separators are disposed in at least one of the first to fourth edge regions; and
the plurality of first separators and the plurality of second separators are alternately arranged in at least one of the first to fourth edge regions where the plurality of first separators are not solely disposed.

18. The electronic device of claim 14, wherein:
the plurality of first separators are disposed in a first portion of the first to fourth edge regions;
the plurality of second separators are disposed in a second portion of the first to fourth edge regions; and
the plurality of first separators and the plurality of second separators are alternately arranged in a third portion of the first to fourth edge regions.

19. A display panel comprising:
a driving element layer comprising a pixel driver;
a plurality of light-emitting elements each comprising a first electrode disposed on the driving element layer, an intermediate layer disposed on the first electrode, and a second electrode disposed on the intermediate layer;
a pixel definition layer disposed on the driving element layer and having a light-emitting opening exposing a portion of the first electrode;
a connection electrode disposed on the pixel definition layer and electrically connecting the pixel driver and the second electrode to each other; and
a plurality of separators disposed on the pixel definition layer and protruding in a thickness direction of the driving element layer,
wherein the plurality of separators comprise:
a plurality of first separators having a symmetrical shape; and
a plurality of second separators having an asymmetrical shape.

20. The display panel of claim 19, further comprising:
a dummy layer disposed on the plurality of first separators; and
an outer dummy layer disposed on the plurality of second separators,
wherein the outer dummy layer is electrically connected to the first electrode.
